(19) United States
(12) Patent Application Publication
(10) Pub. No.: US 2025/0294749 A1
(43) Pub. Date: Sep. 18, 2025

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Beyounghyun Koh, Suwon-si (KR); Hyunju Kim, Suwon-si (KR); Jaehwang Sim, Suwon-si (KR); Hyemi Lee, Suwon-si (KR)

(21) Appl. No.: 18/915,469

(22) Filed: Oct. 15, 2024

(30) Foreign Application Priority Data
Mar. 12, 2024 (KR) 10-2024-0034728

(51) Int. Cl. H10B 43/27; G11C 16/04; H01L 25/065; H10B 41/10; H10B 41/27; H10B 41/35; H10B 43/10; H10B 43/35; H10B 80/00

(52) U.S. Cl. CPC H10B 43/27; G11C 16/0483; H01L 25/0652; H10B 41/10; H10B 41/27; H10B 41/35; H10B 43/10; H10B 43/35; H10B 80/00; H01L 2225/06506; H01L 2225/0651

(57) ABSTRACT

A semiconductor device includes gate electrodes stacked in a first region to form a first stack structure and a second stack structure, a channel structure penetrating through the first and second stack structures, a first mold structure in a second region, an align key structure penetrating through the first mold structure, and a second mold structure on the first mold structure and the align key structure. The second mold structure includes a first interlayer insulating layer, a first horizontal sacrificial layer, a second interlayer insulating layer, and a second horizontal sacrificial layer sequentially stacked on an upper surface of the first mold structure, the first interlayer insulating layer and the first horizontal sacrificial layer are spaced apart from the align key structure in a horizontal direction, and the second interlayer insulating layer covers an upper surface and a portion of a side surface of the align key structure.

### CROSS-REFERENCE TO RELATED APPLICATION(S)

This application claims benefit of priority to Korean Patent Application No. 10-2024-0034728 filed on Mar. 12, 2024, in the Korean Intellectual Property Office, the disclosure of which is herein incorporated by reference in its entirety.

### BACKGROUND

The present disclosure relates to semiconductor devices and data storage systems including the same.

In a data storage system requiring data storage, a semiconductor device capable of storing high-capacity data is desirable. Accordingly, a manner in which the data storage capacity of a semiconductor device increases has been researched. For example, as one method to increase the data storage capacity of a semiconductor device, a semiconductor device including memory cells arranged three-dimensionally, instead of memory cells arranged two-dimensionally, has been proposed.

### SUMMARY

An aspect of the present disclosure is to provide a semiconductor device having improved reliability.

An aspect of the present disclosure is to provide a data storage system including a semiconductor device having improved reliability.

According to an aspect of the present disclosure, a semiconductor device include a semiconductor layer, a plurality of first gate electrodes disposed in a first region of the semiconductor device, wherein the plurality of first gate electrodes are spaced apart from each other and stacked in a first direction perpendicular to an upper surface of the semiconductor layer to form a first stack structure, a plurality of second gate electrodes stacked in the first direction to form a second stack structure, wherein the second stack structure is disposed on the first stack structure, a channel structure including a first channel structure and a second channel structure penetrating through the first stack structure and the second stack structure, respectively, wherein the first channel structure includes an upper end contacting a lower end of the second channel structure and a lower end contacting the semiconductor layer, a first mold structure in a second region, wherein the second region is spaced apart from the first region in a first horizontal direction parallel to the upper surface of the semiconductor layer, an align key structure penetrating through the first mold structure and contacting the semiconductor layer, and a second mold structure disposed on the first mold structure and the align key structure and including a plurality of interlayer insulating layers and a plurality of horizontal sacrificial layers alternately stacked in the first direction, wherein the second mold structure includes a first interlayer insulating layer of the plurality of interlayer insulating layers, a first horizontal sacrificial layer of the plurality of horizontal sacrificial layers, a second interlayer insulating layer of the plurality of interlayer insulating layers, and a second horizontal sacrificial layer of the plurality of horizontal sacrificial layers sequentially stacked on an upper surface of the first mold structure in the first direction. The first interlayer insulating layer and the first horizontal sacrificial layer are spaced apart from the align key structure in a horizontal direction when viewed in a plan view. The second interlayer insulating layer covers an upper surface and a portion of a side surface of the align key structure.

According to an aspect of the present disclosure, a semiconductor device includes a semiconductor layer, a plurality of gate electrodes disposed in a first region of the semiconductor device to form a first stack structure and a second stack structure, wherein the second stack structure is disposed on the first stack structure in a first direction perpendicular to an upper surface of the semiconductor layer, wherein the plurality of gate electrodes are spaced apart from each other and stacked in the first direction, and wherein the plurality of gate electrodes include a plurality of first gate electrodes in the first stack structure and a plurality of second gate electrodes in the second stack structure, a channel structure penetrating through the first stack structure and the second stack structure and contacting the semiconductor layer, a first mold structure in a second region spaced apart from the first region in a first horizontal direction parallel to the upper surface of the semiconductor layer, an align key structure penetrating through the first mold structure, and a second mold structure disposed on the first mold structure and the align key structure and including a first interlayer insulating layer, a first horizontal sacrificial layer, a second interlayer insulating layer and a second horizontal sacrificial layer sequentially stacked on an upper surface of the first mold structure. The first mold structure has a recessed region exposing an upper surface and a portion of a side surface of the align key structure. The first interlayer insulating layer and the first horizontal sacrificial layer are outside the recessed region when viewed in a plan view. A lower surface of a lowermost second gate electrode of the plurality of second gate electrodes in the second stack structure is disposed at a same level as a lower surface of the first horizontal sacrificial layer.

According to an aspect of the present disclosure, a data storage system includes a semiconductor storage device including a semiconductor layer, circuit elements on one side of the semiconductor layer, and an input/output pad electrically connected to the circuit elements, and having first and second regions, and a controller electrically connected to the semiconductor storage device through the input/output pad and configured to control the semiconductor storage device. The semiconductor storage device includes a plurality of gate electrodes disposed in the first region to form a first stack structure and a second stack structure, wherein the second stack structure is disposed on the first stack structure in a first direction perpendicular to an upper surface of the semiconductor layer, wherein the plurality of gate electrodes are spaced apart from each other and stacked in the first direction, and wherein the plurality of gate electrodes include a plurality of first gate electrodes in the first stack structure and a plurality of second gate electrodes in the second stack structure, a channel structure penetrating through the first stack structure and the second stack structure and contacting the semiconductor layer, a first mold structure in the second region, an align key structure penetrating through the first mold structure, and a second mold structure disposed on the first mold structure and the align key structure and including a first interlayer insulating layer, a first horizontal sacrificial layer, and a second interlayer insulating layer sequentially stacked on an upper surface of the first mold structure. The first interlayer insulating layer and the first horizontal sacrificial layer are spaced apart from the align key structure in a horizontal direction parallel to the upper surface of the semiconductor layer. A lowermost second gate electrode of the plurality of second gate electrodes in the second stack structure is disposed at a same level as the first horizontal sacrificial layer.

By optimizing a manufacturing process of an align key structure, a first interlayer insulating layer and a first horizontal sacrificial layer of a second mold structure are arranged to not vertically overlap the align key structure, thereby providing a semiconductor device having improved reliability and a data storage system including the same.

Advantages and effects of the present application are not limited to the foregoing content and may be variously extended without departing from the spirit and domain of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of a semiconductor device according to example embodiments;

FIG. 2 is a schematic cross-sectional view of a semiconductor device according to example embodiments;

FIGS. 3A and 3B are partially enlarged views illustrating partial regions of a semiconductor device according to example embodiments;

FIGS. 4A and 4B are partially enlarged views of a semiconductor device according to example embodiments;

FIGS. 5, 6, 7, and 8 are cross-sectional views of a semiconductor device according to example embodiments;

FIGS. 9A, 9B, 9C, 9D, 9E, 9F, 9G, 9H, 91, 9J, and 9K are schematic cross-sectional views illustrating a method of manufacturing a semiconductor device according to example embodiments;

FIG. 10 is a view schematically illustrating a data storage system including a semiconductor device according to example embodiments;

FIG. 11 is a perspective view schematically illustrating a data storage system including a semiconductor device according to an example embodiment; and

FIG. 12 is a cross-sectional view schematically illustrating a semiconductor package according to an example embodiment.

### DETAILED DESCRIPTION

Hereinafter, example embodiments of the present disclosure will be described with reference to the accompanying drawings.

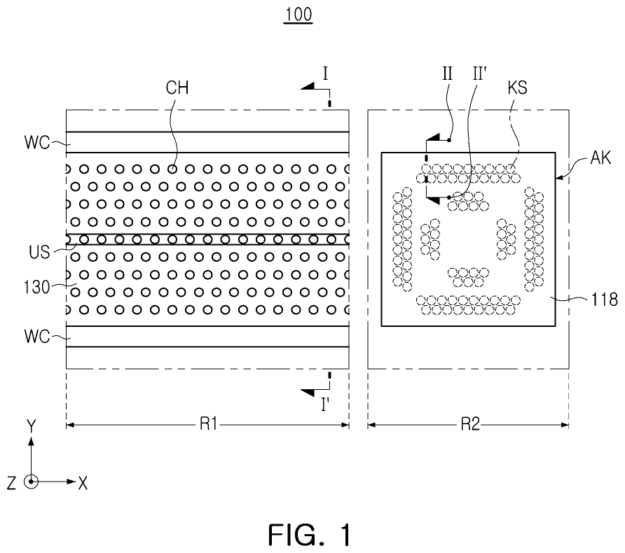

FIG. 1 is a schematic plan view of a semiconductor device according to example embodiments.

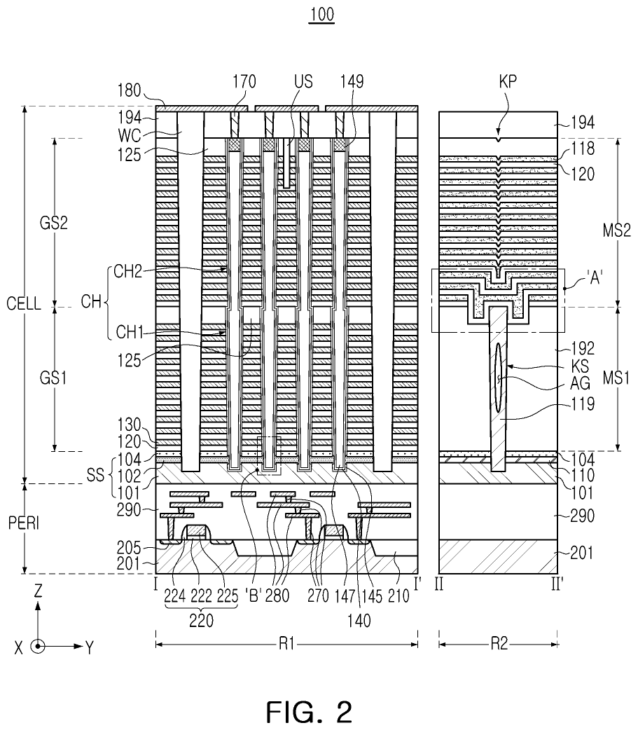

FIG. 2 is a schematic cross-sectional view of a semiconductor device according to example embodiments. FIG. 2 is a cross-sectional view taken along lines I-I′ and II-II′ of FIG. 1.

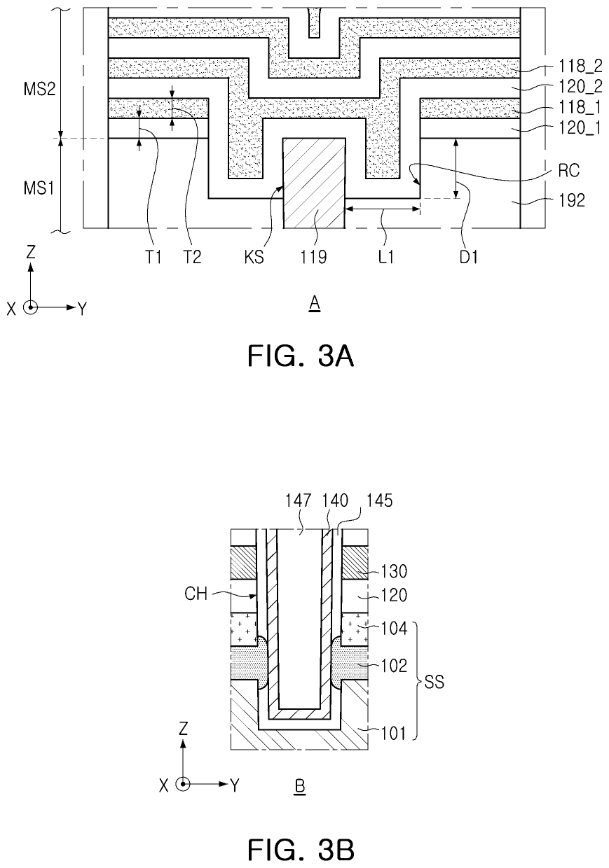

FIGS. 3A and 3B are partially enlarged views illustrating partial regions of a semiconductor device according to example embodiments. In FIG. 3A, an enlarged view of region ‘A’ of FIG. 2 is illustrated, and in FIG. 3B, an enlarged view of region ‘B’ of FIG. 2 is illustrated.

Referring to FIGS. 1, 2, 3A and 3B, a semiconductor device 100 may include a peripheral circuit region PERI, which is a first semiconductor structure including a substrate 201, and a memory cell region CELL, which is a second semiconductor structure including a semiconductor layer 101. The memory cell region CELL may be disposed on the peripheral circuit region PERI. In example embodiments, the memory cell region CELL may be disposed below the peripheral circuit region PERI.

The peripheral circuit region PERI may include the substrate 201, impurity regions 205 and element isolation layers 210 inside the substrate 201, circuit elements 220 disposed on the substrate 201, a peripheral region insulating layer 290, circuit contact plugs 270, and circuit interconnections 280.

The substrate 201 may have an upper surface extending in an X-direction and a Y-direction. An active region may be defined on the substrate 201 by the element isolation layers 210. The X-direction and the Y-direction may be parallel to an upper surface of the substrate 201. The impurity regions 205 including impurities may be disposed in a portion of the active region. The substrate 201 may include a semiconductor material, such as a group IV semiconductor, a group III-V compound semiconductor, and a group II-VI compound semiconductor. The substrate 201 may be provided as a bulk wafer or an epitaxial layer.

The circuit elements 220 may include planar transistors. Each of the circuit element 220s may include a circuit gate dielectric layer 222, a spacer layer 224, and a circuit gate electrode 225. The impurity regions 205 may be disposed as source/drain regions in the substrate 201 on opposite sides of the circuit gate electrode 225.

The peripheral region insulating layer 290 may be disposed on the substrate 201 and cover the circuit element 220. The peripheral region insulating layer 290 may include a plurality of insulating layers formed in different process operations. The peripheral region insulating layer 290 may be formed of an insulating material.

The circuit contact plugs 270 and the circuit interconnections 280 may be included in a circuit interconnection structure electrically connected to the circuit elements 220 and the impurity regions 205. The circuit contact plugs 270 may have a cylindrical shape, and the circuit interconnections 280 may have a line shape. An electrical signal may be applied to the circuit element 220 through the circuit contact plugs 270 and the circuit interconnections 280. In a region not illustrated, the circuit contact plugs 270 may also be connected to the circuit gate electrode 225. The circuit interconnections 280 may be connected to the circuit contact plugs 270 and may be arranged in the form of a plurality of layers. The circuit contact plugs 270 and the circuit interconnections 280 may include a conductive material and may include, for example, tungsten (W), copper (Cu), and aluminum (Al), each of which may further include a diffusion barrier. In example embodiments, the number of layers of circuit contact plugs 270 and circuit interconnections 280 may be variously changed.

The semiconductor device 100 may have first and second regions R1 and R2. In the first region R1, the memory cell region CELL may include first and second horizontal conductive layers 102 and 104 on the semiconductor layer 101, first and second stack structures GS1 and GS2 each including gate electrodes 130 and interlayer insulating layers 120, channel structures CH penetrating through the first and second stack structures GS1 and GS2 and including a channel layer 140, an upper separation region US penetrating through a portion of the second stack structure GS2, separation regions WC penetrating through the first and second stack structures GS1 and GS2, studs 170 on channel structures CH, cell interconnections 180 on the studs 170, and a second cell region insulating layer 194 covering the channel structures CH.

In the second region R2, the memory cell region CELL may include at least one align key AK. In the second region R2, the memory cell region CELL may include a horizontal insulating layer 110, a second horizontal conductive layer 104, a first mold structure MS1 including a first cell region insulating layer 192, a second mold structure MS2 including horizontal sacrificial layers 118 and interlayer insulating layers 120, an align key structure KS penetrating through the first mold structure MS1, and a second cell region insulating layer 194 covering the second mold structure MS2.

In the semiconductor device 100, the first and second regions R1 and R2 may be spaced apart from each other. The first region R1 may be a memory cell region in which memory cell strings are arranged based on the channel structures CH, and the second region R2 is disposed outside the first region R1 and may be a region in which memory cells are not disposed. For example, the second region R2 may be a dummy region. In some example embodiments, the second region R2 may be a scribe lane region. Depending on the method of explanation, the first and second regions R1 and R2 may be referred to as regions of the substrate 201 or the semiconductor layer 101, rather than as regions of the semiconductor device 100.

The semiconductor layer 101 may have an upper surface extending in the X-direction and the Y-direction. The semiconductor layer 101 may include a semiconductor material, such as a group IV semiconductor, a group III-V compound semiconductor, and a group II-VI compound semiconductor. For example, the group IV semiconductors may include silicon, germanium, or silicon-germanium. The semiconductor layer 101 may be provided as a bulk wafer, an epitaxial layer, a silicon on insulator (SOI) layer, or a semiconductor on insulator (SeOI) layer. The semiconductor layer 101 may include impurities.

In an example embodiment, the semiconductor layer 101 may be disposed in both the first and second regions R1 and R2. However, in some example embodiments, the semiconductor layer 101 may be disposed only in the first region R1. In this case, the horizontal insulating layer 110 and the second horizontal conductive layer 104 may not be disposed in the second region R2, and at least one insulating layer may be disposed in a position corresponding to the semiconductor layer 101, the horizontal insulating layer 110, and the second horizontal conductive layer 104.

The first and second horizontal conductive layers 102 and 104 may be sequentially stacked and arranged on an upper surface of the semiconductor layer 101 in the first region R1. The first and second horizontal conductive layers 102 and 104 may be included in a source structure SS together with the semiconductor layer 101. The source structure SS may function as a common source line of the semiconductor device 100. As illustrated in FIG. 3B, the first horizontal conductive layer 102 may be directly connected to the channel layer 140 around the channel layer 140.

The first and second horizontal conductive layers 102 and 104 may include a semiconductor material, for example, polycrystalline silicon. In this case, at least the first horizontal conductive layer 102 may be a layer doped with impurities of the same conductivity type as the semiconductor layer 101. The second horizontal conductive layer 104 may be a doped layer or a layer including impurities diffused from the first horizontal conductive layer 102. In some example embodiments, a relatively thin insulating layer may be interposed between the first horizontal conductive layer 102 and the second horizontal conductive layer 104.

The first and second stack structures GS1 and GS2 may be sequentially stacked from the semiconductor layer 101 in a Z-direction in the first region R1. The Z-direction may be a direction perpendicular to an upper surface of the substrate 201 or an upper surface of the semiconductor layer 101. Each of the first and second stack structures GS1 and GS2 may include gate electrodes 130 and interlayer insulating layers 120 alternately disposed with the gate electrodes 130. Each of the first and second stack structures GS1 and GS2 may further include an upper interlayer insulating layer 125 that is disposed in an uppermost portion and has a relatively thick thickness.

The gate electrodes 130 may be vertically spaced apart from each other and stacked on the semiconductor layer 101 to form the first and second stack structures GS1 and GS2. The gate electrodes 130 may include a lower gate electrode of a ground select transistor, memory gate electrodes of a plurality of memory cells, and upper gate electrodes of string select transistors. The number of the memory gate electrodes may be determined depending on the capacity of the semiconductor device 100. According to an example embodiment, the number of upper and lower gate electrodes may each be 1 to 4 or more, and the upper and lower gate electrodes may have a structure identical to or different from the memory gate electrodes. In example embodiments, the gate electrodes 130 may further include a gate electrode disposed above the upper gate electrodes and/or below the lower gate electrodes and configured to form an erase transistor used in an erase operation using a gate induced drain leakage (GIDL) phenomenon. Some of the gate electrodes 130, for example, memory gate electrodes adjacent to the upper or lower gate electrodes, may be dummy gate electrodes. For example, the gate electrodes 130 may include at least one dummy gate electrode between the upper gate electrode and the memory gate electrodes or between the lower gate electrodes and the memory gate electrodes.

As illustrated in FIG. 1, the gate electrodes 130 may be separated from each other in the Y-direction by separation regions WC. The gate electrodes 130 between a pair of separation regions WC may be included in one memory block, but the range of the memory block is not limited thereto.

The gate electrodes 130 may include a metal material, for example, tungsten (W). According to an example embodiment, the gate electrodes 130 may include polycrystalline silicon or metal silicide material. In example embodiments, the gate electrodes 130 may further include a diffusion barrier. For example, the diffusion barrier may include tungsten nitride (WN), tantalum nitride (TaN), titanium nitride (TiN), or a combination thereof.

The interlayer insulating layers 120 may be disposed between the gate electrodes 130 in the first region R1, and may be disposed between the horizontal sacrificial layers 118 in the second mold structure MS2 in the second region R2. The interlayer insulating layers 120 may also be spaced apart from each other in the Z-direction, and may extend in the X-direction, similarly to the gate electrodes 130 and the horizontal sacrificial layers 118. A relatively thick upper interlayer insulating layer 125 may be disposed on an uppermost portion of the first and second stack structures GS1 and GS2 and the second mold structure MS2. However, the relative thickness and arrangement position of the interlayer insulating layers 120 and the upper interlayer insulating layer 125 may be variously changed in example embodiments. The interlayer insulating layers 120 and the upper interlayer insulating layer 125 may include an insulating material such as silicon oxide and silicon nitride.

Each of the channel structures CH form one memory cell string, and may be spaced apart from each other in rows and columns in the first region R1. The channel structures CH may be arranged to form a grid pattern in an X-Y plane or may be arranged in a zigzag shape in one direction. The channel structures CH have a pillar shape and may have inclined side surfaces that become narrower as they approach the semiconductor layer 101 depending on the aspect ratio.

The channel structures CH may include first and second channel structures CH1 and CH2 that are vertically stacked. The first channel structures CH1 may penetrate through the first stack structure GS1 and may contact the semiconductor layer 101, and the second channel structures CH2 may penetrate through the second stack structure GS2 and may be connected to the first channel structures CH1. The channel structures CH may have a bent portion due to a difference in width in a region in which the first channel structures CH1 and the second channel structures CH2 are connected. For example, at the boundary between the first and second channel structures CH1 and CH2, a first width, in the Y-direction, of an upper end (i.e., a top surface) of the first channel structure CH1 may be different from a second width, in the Y-direction, of a lower end (i.e., a bottom surface) of the second channel structure CH2. The top surface of the first channel structure CH1 may contact the bottom surface of the second channel structure CH2. In an embodiment, the first width of the upper end of the first channel structure CH1 may be greater than the second width of the lower end of the second channel structure CH2. However, according to example embodiments, the number of channel structures stacked in the Z-direction may be variously changed. The term “contact,” as used herein, refers to a direct connection (i.e., physical touching) unless the context indicates otherwise.

Each of the channel structures CH may include a gate dielectric layer 145, a channel layer 140, a channel filling insulating layer 147, and a channel pad 149 sequentially disposed inside a channel hole. The channel layer 140, the gate dielectric layer 145, and the channel filling insulating layer 147 may be connected to each other between the first channel structure CH1 and the second channel structure CH2. As illustrated in FIG. 3B, the channel layer 140 may be formed in an annular shape surrounding the channel filling insulating layer 147, and the channel filling insulating layer 147 may be disposed inside a space defined by the channel layer 140. According to example embodiments, the channel layer 140 may have a pillar shape such as a cylinder and a prism without the channel filling insulating layer 147. The channel layer 140 may be connected to the first horizontal conductive layer 102 at the bottom. The channel layer 140 may include a semiconductor material such as polycrystalline silicon and single crystalline silicon.

The gate dielectric layer 145 may be disposed between the gate electrodes 130 and the channel layer 140. Although not specifically illustrated, the gate dielectric layer 145 may include a tunneling layer, a charge storage layer, and a blocking layer sequentially stacked from the channel layer 140. The tunneling layer may tunnel charges into the charge storage layer, and may include, for example, silicon oxide (SiO₂), silicon nitride (Si₃N₄), silicon oxynitride (SiON), or a combination thereof. The charge storage layer may be a charge trap layer or a floating gate conductive layer. The blocking layer may include silicon oxide (SiO₂), silicon nitride (Si₃N₄), silicon oxynitride (SiON), a high-K dielectric material, or a combination thereof. In example embodiments, at least a portion of the gate dielectric layer 145 may extend in a horizontal direction, such as the X-direction and the Y-direction, along the gate electrodes 130.

The channel pad 149 may be disposed only on an upper end of the upper second channel structure CH2. The channel pad 149 may include, for example, doped polycrystalline silicon.

The separation regions WC may extend in the X-direction by penetrating through the first and second stack structures GS1 and GS2 and the first and second horizontal conductive layers 102 and 104 in the first region R1, and may be connected to the semiconductor layer 101. As illustrated in FIG. 1, the separation regions WC may be arranged in parallel with each other. The separation regions WC may separate the gate electrodes 130 from each other in the Y-direction. The separation regions WC may have a shape of which the width decreases toward the semiconductor layer 101 due to a high aspect ratio. The separation regions WC may include an insulating material, for example, silicon oxide, silicon nitride, or silicon oxynitride.

As illustrate in FIG. 1, the upper separation region US may extend in the X-direction between the separation regions WC adjacent to each other in the Y-direction in the first region R1. The upper separation region US may penetrate through some of the gate electrodes 130 including an uppermost gate electrode, among the gate electrodes 130. As illustrated in FIG. 2, the upper separation region US may separate, for example, a total of three gate electrodes 130 from each other in the Y-direction. However, the number of gate electrodes, among the gate electrodes 130, separated by the upper separation region US may be variously changed in example embodiments. The upper separation region US may include an insulating material, for example, silicon oxide, silicon nitride, or silicon oxynitride.

The second cell region insulating layer 194 may be disposed to cover the second stack structure GS2 and the second mold structure MS2. The second cell region insulating layer 194 may include a plurality of insulating layers according to example embodiments. The second cell region insulating layer 194 may be formed of an insulating material, and may include, for example, at least one of silicon oxide, silicon nitride, and silicon oxynitride.

The studs 170 and the cell interconnections 180 may be disposed on the channel structures CH in the first region R1, and may be included in a cell interconnection structure electrically connected to the memory cells. The studs 170 may penetrate through the second cell region insulating layer 194 and may be connected to the channel structures CH. The studs 170 may electrically connect the channel structures CH to, for example, the cell interconnections 180 corresponding to bit lines. The studs 170 may have a cylindrical shape, and may have an inclined side surface so that a width thereof decreases toward the semiconductor layer 101, depending on the aspect ratio of holes in which the studs 170 are formed. The cell interconnections 180 may have a line shape. In example embodiments, the number of plugs and interconnections included in the cell interconnection structure may be variously changed. The studs 170 and the cell interconnections 180 may not be disposed in the second region R2. The studs 170 and the cell interconnections 180 may be formed of a conductive material and may include, for example, at least one of tungsten (W), aluminum (Al), and copper (Cu).

The first and second mold structures MS1 and MS2 may be sequentially stacked from the semiconductor layer 101 in the Z-direction in the second region R2. An upper surface of the first mold structure MS1 may be disposed at substantially the same level as an upper surface of the first stack structure GS1 and upper surfaces or upper ends of the first channel structures CH1. The second mold structure MS2 may be disposed at substantially the same level as the second stack structure GS2. An upper surface of the second mold structure MS2 may be disposed at substantially the same level as upper surfaces of the second channel structures CH2. Terms such as “same,” “equal,” “planar,” or “coplanar,” as used herein encompass near identicality including variations that may occur, for example, due to manufacturing processes. The term “substantially” may be used herein to emphasize this meaning, unless the context or other statements indicate otherwise.

The first mold structure MS1 may include a first cell region insulating layer 192 disposed on the second horizontal conductive layer 104. Unlike the second mold structure MS2, the first mold structure MS1 may be formed of or may be consisted of a single material. The first cell region insulating layer 192 may include an insulating material, and may include, for example, silicon oxide, silicon nitride, or silicon oxynitride. The first cell region insulating layer 192 may include a plurality of insulating layers stacked in the Z-direction, and even in this case, the plurality of insulating layers may include the same material.

The second mold structure MS2 may be disposed on the first mold structure MS1 and the align key structure KS. The second mold structure MS2 may include the horizontal sacrificial layers 118 and the interlayer insulating layers 120 alternately disposed with the horizontal sacrificial layers 118. The second mold structure MS2 may further include an upper interlayer insulating layer 125 that is disposed in an uppermost portion and has a relatively thick thickness compared to the thicknesses of the horizontal sacrificial layers 118 and the interlayer insulating layers 120. In the second mold structure MS2, the horizontal sacrificial layers 118 may extend horizontally at substantially the same level as the gate electrodes 130 of the second stack structure GS2, respectively. In the second mold structure MS2, the interlayer insulating layers 120 may extend horizontally at substantially the same level as the interlayer insulating layers 120 of the second stack structure GS2, respectively.

The second mold structure MS2 may be disposed in a shape in which the first mold structure MS1, for example, the first cell region insulating layer 192, is recessed to a predetermined thickness around the align key structure KS. Accordingly, the horizontal sacrificial layers 118 and interlayer insulating layers 120 included in the second mold structure MS2 may have key pattern portions KP extending toward the semiconductor layer 101.

The horizontal insulating layer 110 may be disposed in the second region R2 at the same level as the first horizontal conductive layer 102 in the first region R1. The horizontal insulating layer 110 may include a plurality of insulating layers, for example, three insulating layers, alternately stacked on the semiconductor layer 101. The horizontal insulating layer 110 may be layers that remain after a portion of the horizontal insulating layer 110 is replaced with the first horizontal conductive layer 102 during a manufacturing process of a semiconductor device 100c. The horizontal insulating layer 110 may include at least one of silicon oxide, silicon nitride, silicon carbide, and silicon oxynitride.

The horizontal sacrificial layers 118 may be vertically spaced from each other and stacked in the second region R2 of the semiconductor layer 101 to form the second mold structure MS2. The horizontal sacrificial layers 118 may be disposed at the same level as the gate electrodes 130 with substantially the same thickness, respectively. The horizontal sacrificial layers 118 may be formed of an insulating material different from the interlayer insulating layers 120. The horizontal sacrificial layers 118 may include, for example, silicon oxide, silicon nitride, or silicon oxynitride.

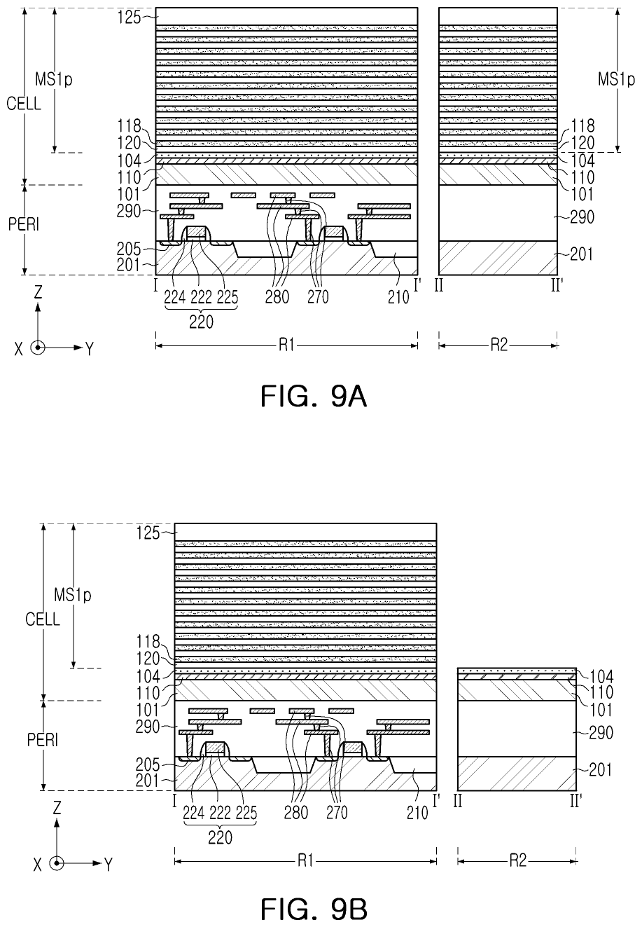

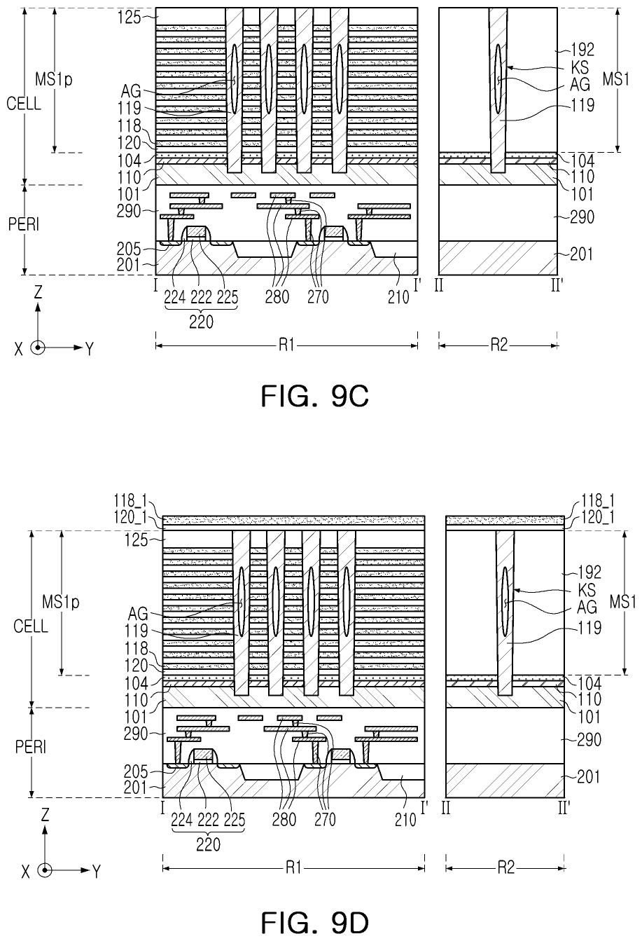

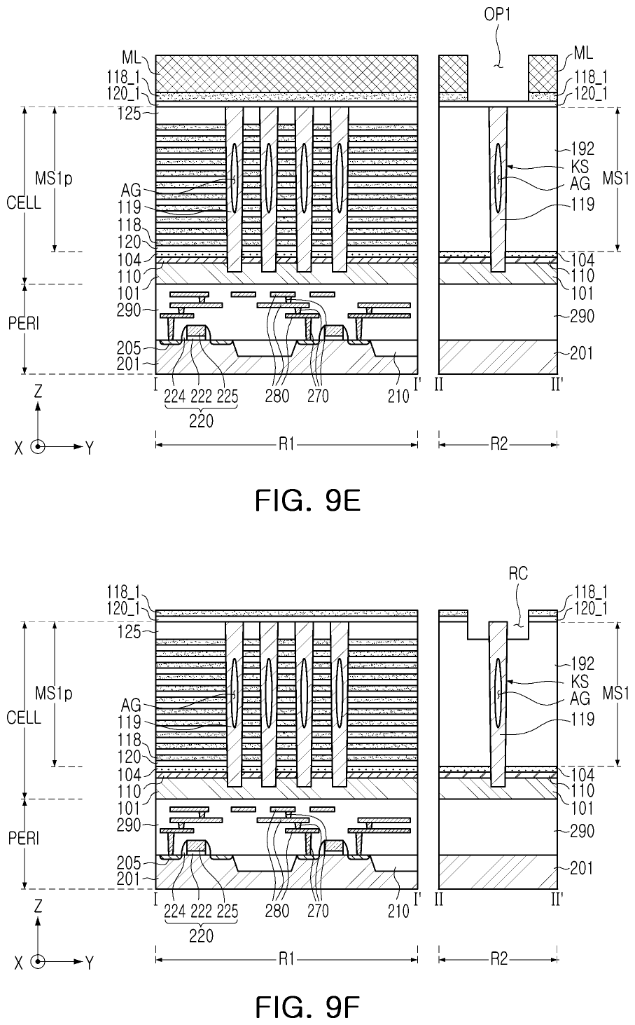

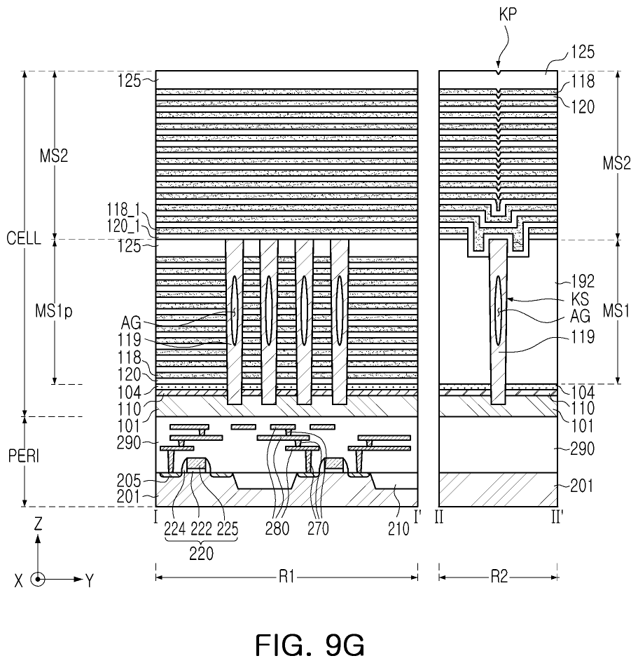

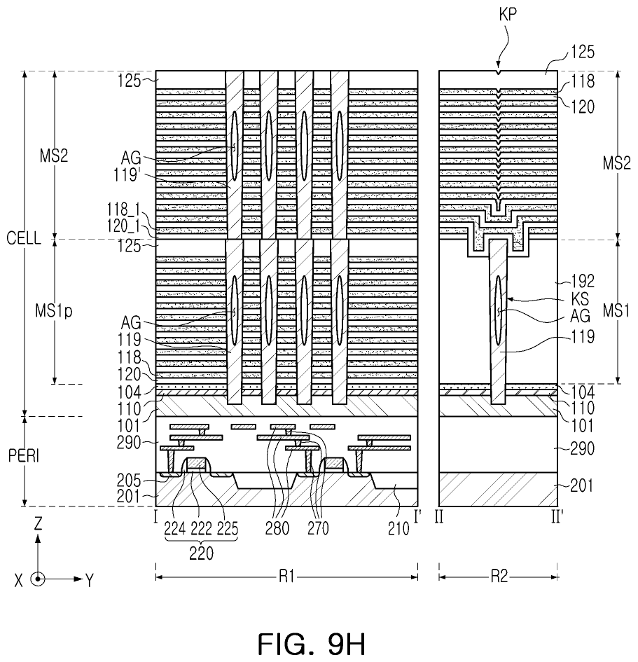

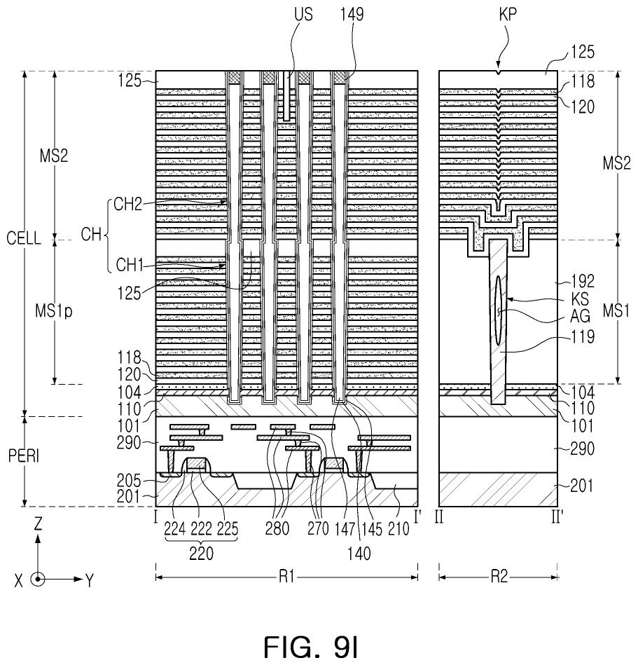

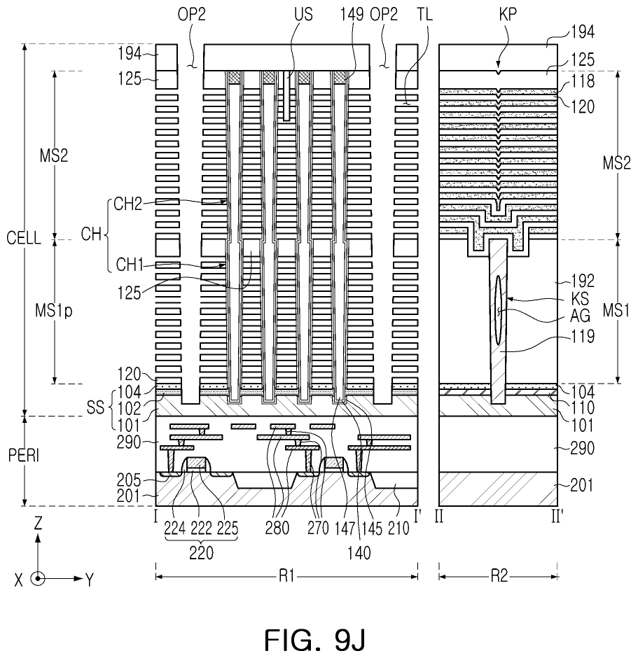

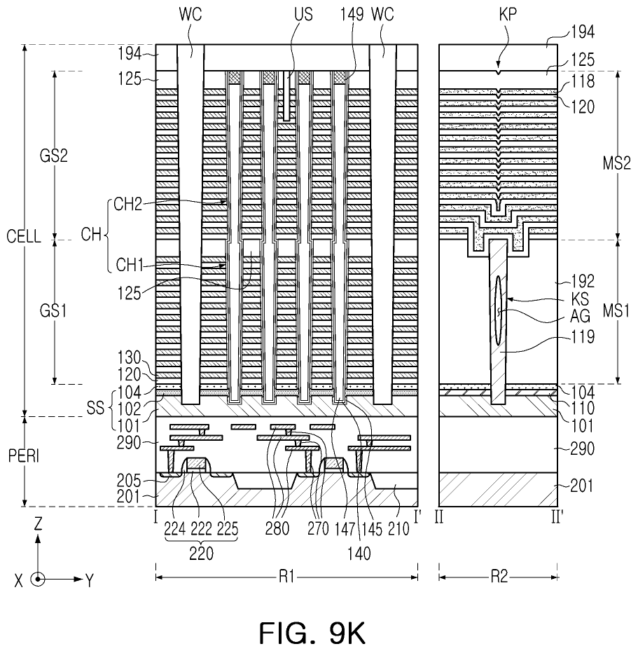

The align key structures KS may be disposed in the second region R2 and may be arranged in a certain pattern inside the align key AK, as illustrated in FIG. 1. The align key AK may be a key for alignment between upper and lower patterns during a photolithography process in a manufacturing process of the semiconductor device 100. For example, the align key structure KS may be used in a process of aligning the second channel structures CH2 with the first channel structures CH1. This will be described in more detail with reference to FIG. 9H below. One or more align keys AK may be disposed, and the shape and size of the pattern formed by the align key structures KS within the align key AK may be variously changed in example embodiments.

The align key structure KS may penetrate through the first mold structure MS1, the horizontal insulating layer 110 and the second horizontal conductive layer 104 and may contact the semiconductor layer 101. An upper surface of the align key structure KS may be disposed at substantially the same level as the upper surface of the first mold structure MS1. The upper surface of the align key structure KS may be disposed at substantially the same level as an upper surface of the first channel structure CH1. The align key structure KS may have an internal structure different from that of the first channel structure CH1. A diameter of the align key structure KS may be equal to or larger than a diameter of the first channel structure CH1. The align key structure KS may have a pillar shape. In some example embodiments, the align key structure KS may have a wall shape extending lengthwise in the X-direction instead of the pillar shape.

The horizontal sacrificial layers 118 and the interlayer insulating layers 120 included in the second mold structure MS2 may extend horizontally on the align key structure KS. The align key structure KS may overlap the horizontal sacrificial layers 118 in the Z-direction.

The align key structure KS may include a vertical sacrificial layer 119. The vertical sacrificial layer 119 may include a carbon (C) material or a carbon-based material. For example, the vertical sacrificial layer 119 may be consisted of a single material layer including carbon (C) material. The vertical sacrificial layer 119 may include a material different from the interlayer insulating layers 120 and the horizontal sacrificial layers 118. The vertical sacrificial layer 119 may include or may be consisted of, for example, an amorphous carbon layer (ACL), but the present disclosure is not limited thereto. The align key structure KS may include an air gap AG therein, but the present disclosure is not limited thereto. The term “air” as discussed herein, may refer to atmospheric air, or other gases that may be present during the manufacturing process.

Referring to FIG. 3A, the first mold structure MS1, for example, the first cell region insulating layer 192, may have a recessed region RC surrounding the align key structure KS. The align key structure KS may protrude into the recessed region RC. Through the recessed region RC, the upper surface of the align key structure KS and a portion of a side surface extending from the upper surface may be exposed. For example, a depth D1 of the recessed region RC may be equal to or less than a thickness of the upper interlayer insulating layer 125 of the first stack structure GS1. A length L1 of the recessed region RC from the align key structure KS may be variously changed in example embodiments.

The second mold structure MS2 may include a first interlayer insulating layer 120_1, a first horizontal sacrificial layer 118_1, a second interlayer insulating layer 120_2, and a second horizontal sacrificial layer 118_2, sequentially stacked from the upper surface of the first mold structure MS1. The first interlayer insulating layer 120_1 and the second interlayer insulating layer 120_2 may be disposed at substantially the same level as a lowermost interlayer insulating layer of the interlayer insulating layers 120 in the second stack structure GS2 and an interlayer insulating layer disposed thereon, respectively. The first horizontal sacrificial layer 118_1 and the second horizontal sacrificial layer 118_2 may be disposed at substantially the same level as a lowermost gate electrode of the gate electrodes 130 in the second stack structure GS2 and a gate electrode disposed thereon, respectively. For example, a lower surface of the first horizontal sacrificial layer 118_1 may be disposed at substantially the same level as a lower surface of the lowermost gate electrode of the gate electrodes 130 in the second stack structure GS2.

The first interlayer insulating layer 120_1 and the first horizontal sacrificial layer 118_1 may be spaced apart from the align key structure KS in the horizontal direction, for example, in the X-direction and the Y-direction. For example, the first interlayer insulating layer 120_1 and the first horizontal sacrificial layer 118_1 may be spaced apart from the align key structure KS in the horizontal direction when viewed in a plan view. The first interlayer insulating layer 120_1 and the first horizontal sacrificial layer 118_1 may be disposed outside the align key structure KS and may not extend onto the align key structure KS, and may not overlap the align key structure KS in the Z-direction. For example, the first interlayer insulating layer 120_1 and the first horizontal sacrificial layer 118_1 may be disposed outside the align key structure KS when viewed in the plan view. A side surface of the first interlayer insulating layer 120_1 and a side surface of the first horizontal sacrificial layer 118_1 may be substantially coplanar with each other, and may also be coplanar with a sidewall of the recessed region RC. A first thickness T1 of the first interlayer insulating layer 120_1 may be equal to or less than a second thickness T2 of the first horizontal sacrificial layer 118_1, but the present disclosure is not limited thereto. The second thickness T2 may be substantially the same as a thickness of the lowermost gate electrode 130 disposed at the same level in the second stack structure GS2. For example, the second thickness T2 may have a value in a range of from about 230 Å to about 270 Å. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The second interlayer insulating layer 120_2 may be disposed on the first horizontal sacrificial layer 118_1, and may extend vertically while covering a side surface of the first interlayer insulating layer 120_1 and a side surface of the first horizontal sacrificial layer 118_1 and may extend conformally along the sidewall and a bottom surface of the recessed region RC. The second interlayer insulating layer 120_2 may cover an upper surface and a portion of a side surface of the align key structure KS exposed through the recessed region RC. A lower surface of the second interlayer insulating layer 120_2 may be disposed at a first level on the align key structure KS, may be disposed at a second level lower than the first level on the first mold structure MS1 around the align key structure KS, and may be disposed at a third level higher than the first level on the first horizontal sacrificial layer 118_1. In an embodiment, the second interlayer insulating layer 120_2 may include a first horizontal portion on the upper surface of the align key structure KS, a second horizontal portion on a recessed upper surface of the first mold structure MS1 around the align key structure KS, and a third horizontal portion on an upper surface of the first horizontal sacrificial layer 118_1. The first horizontal portion may be higher than the second horizontal portion and lower than the third horizontal portion.

The second horizontal sacrificial layer 118_2 may be disposed on the second interlayer insulating layer 120_2 and may include a region extending vertically toward the recessed region RC. In this example embodiment, the second horizontal sacrificial layer 118_2 may completely fill the recessed region RC together with the second interlayer insulating layer 120_2.

The second interlayer insulating layer 120_2, the second horizontal sacrificial layer 118_2, and other interlayer insulating layers 120 and other horizontal sacrificial layers 118 formed thereon may each have key pattern portions KP in a recess shape corresponding to a center of the align key structure KS. However, while moving upwardly, the key pattern portions KP may have a shape that gradually becomes gentler. For example, the higher the key pattern portions KP are positioned, the smaller the shape of the key pattern portions KP becomes. The key pattern portions KP may be positioned at upper surfaces of the interlayer insulating layers 120 and upper surfaces of the horizontal sacrificial layers 118. The key pattern portions KP may function as an align key for alignment between upper and lower patterns during the manufacturing process of the semiconductor device 100, as described above.

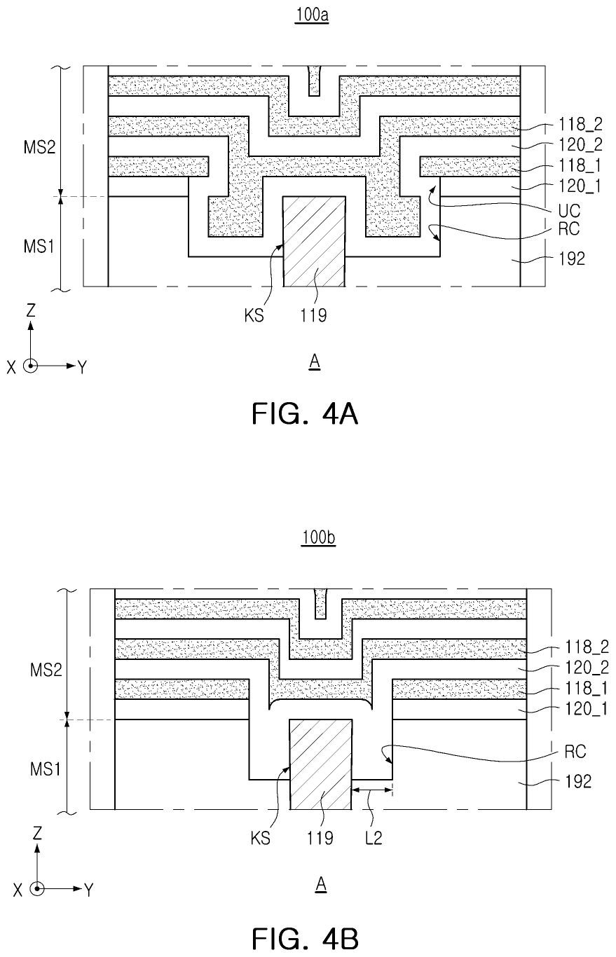

FIGS. 4A and 4B are partially enlarged views of a semiconductor device according to example embodiments. FIGS. 4A and 4B illustrate regions corresponding to FIG. 3A.

Referring to FIG. 4A, in a semiconductor device 100a, in a region adjacent to an align key structure KS, a side surface of a first interlayer insulating layer 120_1 may be disposed outside a side surface of a first horizontal sacrificial layer 118_1. A portion of a lower surface of the first horizontal sacrificial layer 118_1 may be exposed through the first interlayer insulating layer 120_1. An undercut region UC may be formed between the first interlayer insulating layer 120_1 and the first horizontal sacrificial layer 118_1. Accordingly, a profile of at least some layers of horizontal sacrificial layers 118 and interlayer insulating layers 120 disposed on the first horizontal sacrificial layer 118_1 and the first interlayer insulating layer 120_1 may be changed. For example, the second interlayer insulating layer 120_2 may be conformally formed on an upper surface of a combined structure of the first horizontal sacrificial layer 118_1, the first interlayer insulating layer 120_1, and the vertical sacrificial layer 119 disposed in the recessed region RC, and the second horizontal sacrificial layer 118_2 may be conformally formed on an upper surface of the second interlayer insulating layer 120_2. The shape of the upper surface of the combined structure may be transferred to a shape of an upper surface of the second interlayer insulating layer 120_2, and the shape of the upper surface of the second interlayer insulating layer 120_2 may be transferred to a shape of an upper surface of the second horizontal sacrificial layer 118_2. In this manner, the shape of the upper surface of the combined structure having the recessed region RC may be transferred to a shape of an upper surface of an uppermost horizontal sacrificial layer in the shape of the key pattern portions KP, and thus the shape of the upper surface of the combined structure may affect the shapes and locations of the key pattern portions KP. When the vertical sacrificial layer 119 is asymmetric due to damage thereon, the locations of the key pattern portion KP, when viewed in a plan view, may be shifted from a center of the vertical sacrificial layer 119 if not damaged.

Referring to FIG. 4B, in a semiconductor device 100b, a size of a recessed region RC exposing the align key structure KS may be relatively small, and accordingly, layers filling the recessed region RC may be different from those in the example embodiment of FIG. 3A. In an example embodiment, a length L2 from one side of the align key structure KS in the recessed region RC may be shorter than the length L1 in the example embodiment of FIG. 3A. Accordingly, a second interlayer insulating layer 120_2 may fill the recessed region RC. In this manner, in example embodiments, the size of the recessed region RC may be variously changed, and a specific shape of layers of a second mold structure MS2 on the align key structure KS may also be changed accordingly.

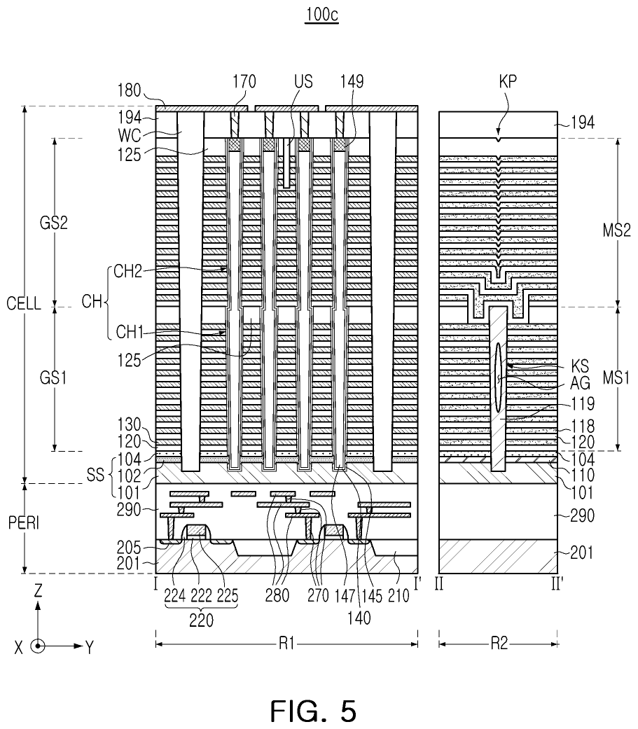

FIGS. 5, 6, 7, and 8 are cross-sectional views of a semiconductor device according to example embodiments. FIGS. 5 to 8 illustrate regions corresponding to FIG. 2.

Referring to FIG. 5, in a semiconductor device 100c, a structure of a first mold structure MS1 may be different from the structure of the first mold structure MS1 in the example embodiment of FIG. 2.

The first mold structure MS1 may include interlayer insulating layers 120 and horizontal sacrificial layers 118, which are alternately stacked, similarly to the second mold structure MS2, and may further include an upper interlayer insulating layer 125 disposed on an uppermost portion of the first mold structure MS1. In the first mold structure MS1, the interlayer insulating layers 120 may be disposed at substantially the same level as interlayer insulating layers 120 of a first stack structure GS1, respectively. In the first mold structure MS1, the horizontal sacrificial layers 118 may be disposed at substantially the same level as gate electrodes 130 of the first stack structure GS1, respectively.

The upper interlayer insulating layer 125 of the first mold structure MS1 may be partially removed to have a recessed region. For example, the upper interlayer insulating layer 125 may be removed to a depth equivalent to a thickness thereof in a region surrounding an align key structure KS. However, in example embodiments, the depth at which the upper interlayer insulating layer 125 is recessed may be variously changed. The align key structure KS may be connected to the semiconductor layer 101 by penetrating through the interlayer insulating layers 120, the horizontal sacrificial layers 118, the horizontal insulating layer 110, and the second horizontal conductive layer 104.

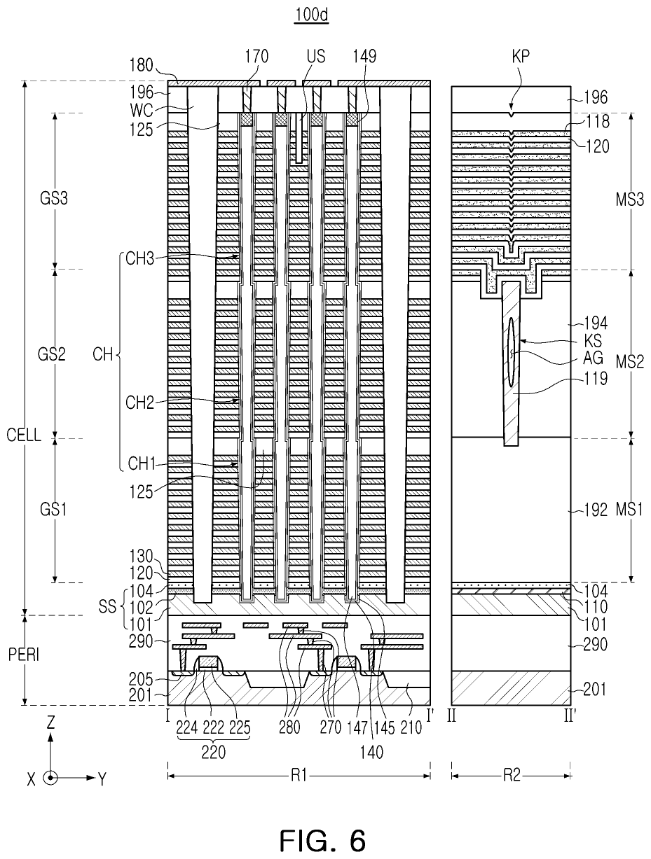

Referring to FIG. 6, a semiconductor device 100d may further include a third stack structure GS3, a third mold structure MS3, and a third cell region insulating layer 196. A channel structure CH may further include a third channel structure CH3. A first mold structure MS1 may include a first cell region insulating layer 192, a second mold structure MS2 may include a second cell region insulating layer 194, and the third mold structure MS3 may include interlayer insulating layers 120 and horizontal sacrificial layers 118, which are alternately stacked.

The third stack structure GS3 may include interlayer insulating layers 120 and gate electrodes 130, which are alternately stacked, and may further include an interlayer insulating layer 125 in an uppermost portion of the third stack structure GS3. The third channel structure CH3 may be connected to a second channel structure CH2 by penetrating through the third stack structure GS3, and may include a channel pad 149 disposed on an upper end of the third channel structure CH3.

The align key structure KS may penetrate through the second mold structure MS2. The interlayer insulating layers 120 and horizontal sacrificial layers 118 included in the third mold structure MS3 may have key pattern portions KP. The explanation described above with reference to FIG. 3A may be equally applied to the align key structure KS and the structure of the layers of the third mold structure MS3 on the align key structure KS. The align key structure KS may be used so that a channel hole in which the third channel structure CH3 is disposed is formed to be aligned with a channel hole of the second channel structure CH2, during manufacturing of the semiconductor device 100d.

In this manner, in example embodiments, the number of stack structures and mold structures stacked in the Z-direction may be variously changed, and accordingly, a level on which the align key structure KS is arranged may also be changed.

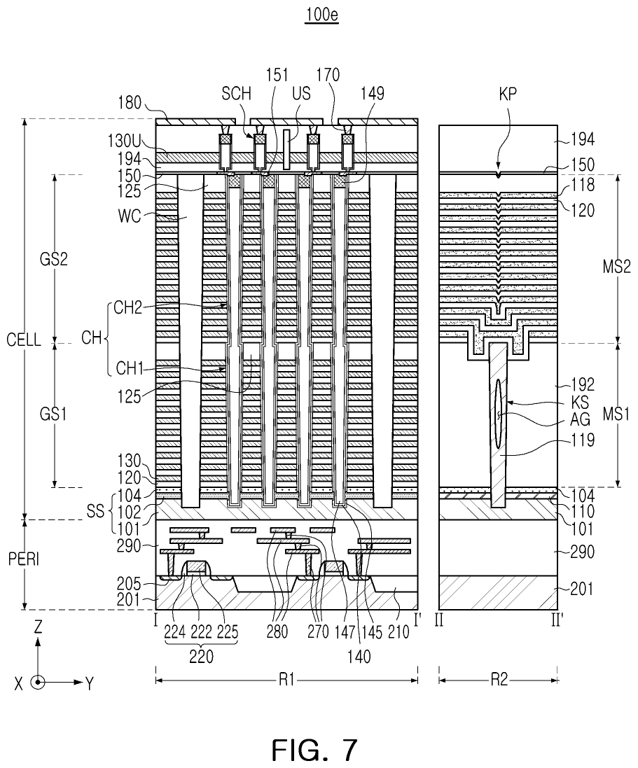

FIG. 7 is a schematic cross-sectional view of a semiconductor device according to example embodiments.

Referring to FIG. 7, a memory cell region CELL of a semiconductor device 100e may further include a horizontal insulating layer 150 and string channel structures SCH connected to channel structures CH.

Among the gate electrodes 130, an upper gate electrode 130U in an uppermost portion may be disposed to be relatively thick as compared to the other gate electrodes 130. The string channel structures SCH may penetrate through the upper gate electrode 130U, and the channel structures CH may penetrate through the gate electrodes 130 except for the upper gate electrode 130U. The upper gate electrode 130U may be divided by an upper separation region US.

The string channel structures SCH may be respectively connected to the channel structures CH. The string channel structures SCH may be disposed on the channel structures CH, respectively, and may be disposed to be shifted from the channel structures CH in the horizontal direction (e.g., the Y-direction), but the present disclosure not limited thereto. Each of the string channel structures SCH may include a string channel layer disposed in a string channel hole, and may have a structure identical to or similar to the channel structures CH. The string channel layer may include a lower end connected to a connection pad 151, and may be electrically connected to a channel layer 140 of the channel structure CH through a connection pad 151. The connection pad 151 may include a conductive material, for example, polycrystalline silicon.

The horizontal insulating layer 150 may be disposed between the channel structures CH and the string channel structures SCH, and may be extended horizontally. The horizontal insulating layer 150 may be disposed between the upper gate electrode 130U and the other gate electrodes 130. The horizontal insulating layer 150 may be used as an etch stop layer when forming the string channel structures SCH, and may be a layer that is also used when forming the connection pads 151. The horizontal insulating layer 150 may also be disposed in a second region R2, but in some example embodiments, the horizontal insulating layer 150 may not be disposed in the second region R2. The horizontal insulating layer 150 may include an insulating material, and may include a different material from interlayer insulating layers 120 and a second cell region insulating layer 194. In the first region R1, the second cell region insulating layer 194 may be disposed above and below the upper gate electrode 130U.

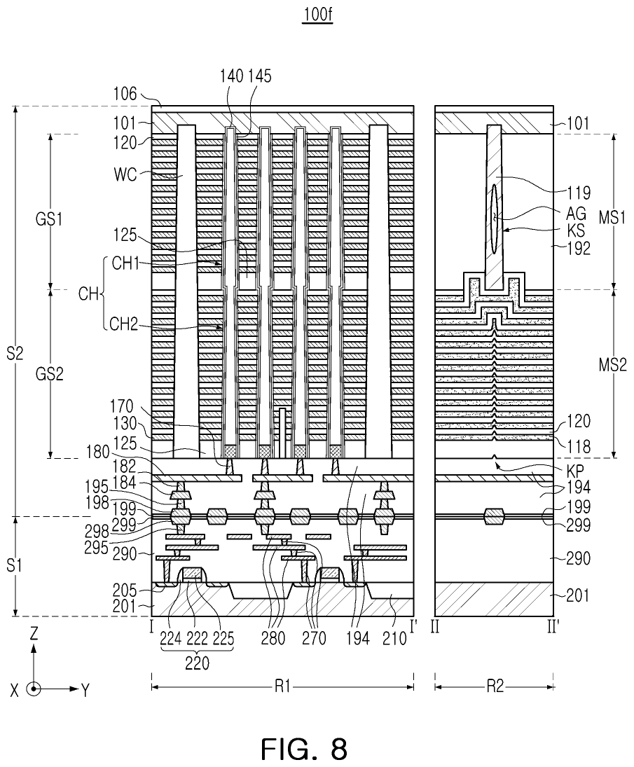

Referring to FIG. 8, a semiconductor device 100f may include a first semiconductor structure S1 and a second semiconductor structure S2 bonded using a wafer bonding method.

The description of the peripheral circuit region PERI described above with reference to FIG. 2 may be applied to the first semiconductor structure S1. However, the first semiconductor structure S1 may further include first bonding vias 295, first bonding metal layers 298, and a first bonding insulating layer 299, which are bonding structures. The first bonding vias 295 may be disposed on an uppermost portion of circuit interconnections 280, and may be connected to the circuit interconnections 280. At least a portion of the first bonding metal layers 298 may be connected to the first bonding vias 295. The first bonding metal layers 298 may be connected to the second bonding metal layers 198 of the second semiconductor structure S2. The first bonding metal layers 298 and the second bonding metal layers 198 may provide an electrical connection path between the first semiconductor structure S1 and the second semiconductor structure S2. Some of the first bonding metal layers 298 may be disposed only for bonding without connections to the circuit interconnections 280. The first bonding vias 295 and the first bonding metal layers 298 may include a conductive material, for example, copper (Cu). The first bonding insulating layer 299 may be disposed around the first bonding metal layers 298. The first bonding insulating layer 299 may also function as a diffusion barrier of the first bonding metal layers 298 and may include, for example, at least one of SiN, SiON, SiCN, SiOC, SiOCN, and SiO.

The description of the memory cell region CELL described above with reference to FIGS. 1, 2, 3A and 3B may be applied to the second semiconductor structure S2 unless otherwise specified. The second semiconductor structure S2 may further include lower contact plugs 182 and lower cell interconnections 184, which are interconnection structures, and may further include second bonding vias 195, second bonding metal layers 198, and second bonding insulating layer 199, which are bonding structures. The second semiconductor structure S2 may further include a passivation layer 106 covering an upper surface of the semiconductor layer 101.

The lower cell interconnections 184 may be electrically connected to the cell interconnections 180 by the lower contact plugs 182. However, in example embodiments, the number of layers and arrangement forms of contact plugs and interconnections included in the interconnection structure may be variously changed. The lower contact plugs 182 and the lower cell interconnections 184 may be formed of a conductive material and may include, for example, at least one of tungsten (W), aluminum (Al), and copper (Cu).

The second bonding vias 195 and the second bonding metal layers 198 may be disposed below the lower cell interconnections 184. The second bonding vias 195 may connect the lower cell interconnections 184 to the second bonding metal layers 198, and the second bonding metal layers 198 may be bonded to the first bonding metal layers 298 of the first semiconductor structure S1. The second bonding insulating layer 199 may be bonded and connected to the first bonding insulating layer 299 of the first semiconductor structure S1. The second bonding vias 195 and the second bonding metal layers 198 may include a conductive material, for example, copper (Cu). The second bonding insulating layer 199 may include, for example, at least one of SiO, SiN, SiCN, SiOC, SiON, and SiOCN.

The first and second semiconductor structures S1 and S2 may be formed by bonding the first bonding metal layers 298 and the second bonding metal layers 198 and bonding the first bonding insulating layer 299 and the second bonding insulating layer 199. The bonding of the first bonding metal layers 298 and the second bonding metal layers 198 may be, for example, copper (Cu)-to-copper (Cu) bonding, and the bonding of the first bonding insulating layer 299 and the second bonding insulating layer 199 may be, for example, dielectric-to-dielectric bonding such as SiCN-to-SiCN bonding. The first and second semiconductor structures S1 and S2 may be bonded by hybrid bonding including the copper (Cu)-to-copper (Cu) bonding and the dielectric-to-dielectric bonding.

In an example embodiment, the second semiconductor structure S2 may not include the first and second horizontal conductive layers 102 and 104 (see FIG. 2). The channel structures CH may be directly connected to the semiconductor layer 101 with the channel layers 140 exposed through an upper end thereof. However, an electrical connection form of the channel structures CH and a common source line may be variously changed in example embodiments, and the channel structures CH and the source structures SS may have the same structure as the example embodiment of FIG. 2.

A passivation layer 106 may be disposed on the upper surface of the semiconductor layer 101 and may protect the semiconductor device 100f. The passivation layer 106 may include at least one of an insulating material, for example, silicon oxide, silicon nitride, and silicon carbide.

FIGS. 9A, 9B, 9C, 9D, 9E, 9F, 9G, 9H, 91, 9J, and 9K are schematic cross-sectional views illustrating a method of manufacturing a semiconductor device according to example embodiments. FIGS. 9A, 9B, 9C, 9D, 9E, 9F, 9G, 9H, 91, 9J, and 9K illustrate cross-sections corresponding to FIG. 2.

Referring to FIG. 9A, a first preliminary mold structure MS1p may be formed by forming a peripheral circuit region PERI, and then forming a horizontal insulating layer 110 and a second horizontal conductive layer 104 on the semiconductor layer 101, and alternately stacking horizontal sacrificial layers 118 and interlayer insulating layers 120.

First, element isolation layers 210 may be formed in a substrate 201, and a circuit gate dielectric layer 222 and a circuit gate electrode 225 may be sequentially formed on the substrate 201. The element isolation layers 210 may be formed in, for example, a shallow trench isolation (STI) process. The circuit gate dielectric layer 222 and the circuit gate electrode 225 may be formed using atomic layer deposition (ALD) or chemical vapor deposition (CVD). The circuit gate dielectric layer 222 may be formed of silicon oxide, and the circuit gate electrode 225 may be formed of at least one of a polycrystalline silicon layer and a metal silicide layer, but the present disclosure is not limited thereto. Next, a spacer layer 224 and impurity regions 205 may be formed on opposite sidewalls of the circuit gate dielectric layer 222 and the circuit gate electrode 225. According to example embodiments, the spacer layer 224 may be formed of a plurality of layers. The impurity regions 205 may be formed by performing an ion implantation process.

Circuit contact plugs 270, between the circuit interconnections 280, may be formed by forming a portion of the peripheral region insulating layer 290, and then etching and removing a portion thereof and filling the removed portion with a conductive material. The circuit interconnections 280 may be formed, for example, by depositing the conductive material and then patterning the conductive material.

The peripheral region insulating layer 290 may be formed of a plurality of insulating layers. The peripheral region insulating layer 290 may include a plurality of insulating layers formed through respective steps of forming the circuit interconnection structure. Accordingly, a peripheral circuit region PERI may be formed.

The semiconductor layer 101 may be formed on the peripheral region insulating layer 290. The semiconductor layer 101 may be formed of, for example, polycrystalline silicon and may be formed through a CVD process. Polycrystalline silicon included in the semiconductor layer 101 may include impurities.

The horizontal insulating layer 110 may include a plurality of layers containing different materials. The horizontal insulating layer 110 may be layers replaced with the first horizontal conductive layer 102 (see FIG. 2) through a subsequent process. For example, the horizontal insulating layer 110 may include a first layer and a third layer formed of the same material as the interlayer insulating layers 120, and may further include a second layer formed of the same material as the horizontal sacrificial layers 118 and disposed between the first layer and the third layer. The second horizontal conductive layer 104 may be formed on the horizontal insulating layer 110.

In the first preliminary mold structure MS1p, the horizontal sacrificial layers 118 may be a layer replaced with the gate electrodes 130 (see FIG. 2) in a first region R1 through a subsequent process. The horizontal sacrificial layers 118 may be formed of a material different from the interlayer insulating layers 120, and may be formed of a material that may be etched with etch selectivity under specific etching conditions for the interlayer insulating layers 120. For example, the interlayer insulating layer 120 may be formed of at least one of silicon oxide and silicon nitride, and the horizontal sacrificial layers 118 may be formed of a material different from the interlayer insulating layer 120 selected from silicon, silicon oxide, silicon carbide, and silicon nitride. In some example embodiments, the thicknesses of the interlayer insulating layers 120 may not all be the same. A relatively thick upper interlayer insulating layer 125 may be formed in an uppermost portion of the first preliminary mold structure MS1p. In example embodiments, the thickness of the interlayer insulating layers 120 and the horizontal sacrificial layers 118 and the number of included films may be variously changed from those shown.

Referring to FIG. 9B, the first preliminary mold structure MS1p may be removed from a second region R2.

The first preliminary mold structure MS1p may be removed through an etching process. The horizontal insulating layer 110 and the second horizontal conductive layer 104 may remain without being removed. However, in some example embodiments, the horizontal insulating layer 110 and the second horizontal conductive layer 104 may also be removed along with the first preliminary mold structure MS1p. In some example embodiments, the semiconductor layer 101 may also be removed along with the first preliminary mold structure MS1p. In the case of the example embodiment of FIG. 5, the semiconductor device may be manufactured by omitting this process step.

Referring to FIG. 9C, a first cell region insulating layer 192 may be formed in the second region R2, and vertical sacrificial layers 119 may be formed in the first and second regions R1 and R2.

The first cell region insulating layer 192 may be formed to have an upper surface coplanar with the first preliminary mold structure MS1p through a planarization process. The first cell region insulating layer 192 may form the first mold structure MS1 of the second region R2.

The vertical sacrificial layers 119 may be formed in regions corresponding to the first channel structures CH1 and the align key structure KS of FIG. 2. The vertical sacrificial layers 119 may be formed by forming lower channel holes to penetrate through the first preliminary mold structure MS1p and the first mold structure MS1, and then depositing materials included in the vertical sacrificial layers 119 in the lower channel holes and performing a planarization process thereon. The vertical sacrificial layers 119 may include carbon or a carbon-based material.

Referring to FIG. 9D, a first interlayer insulating layer 120_1 and a first horizontal sacrificial layer 118_1 may be formed on the first preliminary mold structure MS1p and the first mold structure MS1.

The first interlayer insulating layer 120_1 may be formed to cover upper surfaces of the vertical sacrificial layers 119, and the first horizontal sacrificial layer 118_1 may be formed on the first interlayer insulating layer 120_1. The first interlayer insulating layer 120_1 may include a material different from the vertical sacrificial layers 119 and the first horizontal sacrificial layer 118_1. For example, the vertical sacrificial layers 119 include carbon, the first interlayer insulating layer 120_1 includes oxide, and the first horizontal sacrificial layer 118_1 may include nitride. In this process step, the first horizontal sacrificial layer 118_1 may be formed to be relatively thin as compared to the final structure of FIG. 2.

Referring to FIG. 9E, a mask layer ML exposing a portion of the first horizontal sacrificial layer 118_1 may be formed in the second region R2, and the exposed first horizontal sacrificial layer 118_1 may be removed.

The mask layer ML may be, for example, a photoresist layer. The mask layer ML may be patterned and formed to have a first opening OP1 partially exposing a portion of the first horizontal sacrificial layer 118_1 in the second region R2. Specifically, the first opening OP1 of the mask layer ML may expose a portion of the first horizontal sacrificial layer 118_1 on the vertical sacrificial layer 119 in the second region R2.

The first horizontal sacrificial layer 118_1 exposed through the first opening OP1 may be removed using, for example, a dry etching process. During the etching process, only the first horizontal sacrificial layer 118_1 may be selectively removed so that the first interlayer insulating layer 120_1 remains.

Referring to FIG. 9F, the mask layer ML may be removed, and the first interlayer insulating layer 120_1 and the first mold structure MS1 may be partially removed so that the vertical sacrificial layer 119 is exposed in the second region R2 using the first horizontal sacrificial layer 118_1 as an etch mask.

The mask layer ML may be removed by ashing and strip processes. In this process step, the mask layer ML may be removed in a state in which the vertical sacrificial layers 119 is not exposed. Accordingly, even if the vertical sacrificial layers 119 are formed of a carbon material, the vertical sacrificial layers 119 may be covered with the first interlayer insulating layer 120_1 and may thus be protected from damage. Accordingly, the vertical sacrificial layer 119 may be consisted of a single material containing carbon, and there is no need to adopt a double-layer structure in which an upper portion of the vertical sacrificial layer 119 is filled with a material other than carbon.

The first interlayer insulating layer 120_1 exposed from the first horizontal sacrificial layer 118_1 in the second region R2 may be removed, and the first cell region insulating layer 192 included in the first mold structure MS1 may be partially removed, and thus, a recessed region RC may be formed so that an upper end of the vertical sacrificial layer 119 is exposed. This process step may be performed using an opening of the first horizontal sacrificial layer 118_1 as an etch mask without forming a separate mask layer, and may be performed in a dry etching process or a wet etching process. During the etching process, the first horizontal sacrificial layer 118_1 may also be partially removed so that the thickness of the first horizontal sacrificial layer 118_1 may be reduced.

The recessed region RC of the first mold structure MS1 may be a region surrounding the vertical sacrificial layer 119 in the second region R2. In example embodiments, the width and depth at which the first mold structure MS1 is recessed along a circumference of the vertical sacrificial layer 119 may be variously changed. For the example embodiment of FIG. 4A, in this process step, the semiconductor device may be manufactured by forming the recessed region RC using the wet etching process. For example, during the wet etching process using the first horizontal sacrificial layer 118_1 as an etching mask, a portion of the 120_1 and the first cell region insulating layer 192 included in the first mold structure MS1 under the first horizontal sacrificial layer 118_1 may be partially removed, thereby forming. an undercut below the first horizontal sacrificial layer 118_1.

Referring to FIG. 9G, on the first horizontal sacrificial layer 118_1, a second mold structure MS2 may be formed by alternately stacking the horizontal sacrificial layers 118 and the interlayer insulating layers 120. When the vertical sacrificial layer 119 is damaged, the horizontal sacrificial layers 118 and the interlayer insulating layers 120 may be formed on the damaged vertical sacrificial layer 119. Since the horizontal sacrificial layers 118 and the interlayer insulating layers 120 are conformally formed on the damaged vertical sacrificial layer 119, the key patterns KP formed at the upper surface of the horizontal sacrificial layers 118 and the interlayer insulating layers 120 may be shifted from the center of the vertical sacrificial layer 119 if not damaged when viewed in a plan view. Such shifting of the key patterns KP may make the key patterns KP improper align keys in a photolithography process for forming the upper channel holes which will be discussed below with reference to FIG. 9H. For example, the damage of the vertical sacrificial layer 119 may include removal of at least one corner of an upper end of the vertical sacrificial layer 119.

The second mold structure MS2 may be formed by alternately stacking the horizontal sacrificial layers 118 and the interlayer insulating layers 120 and stacking an upper interlayer insulating layer 125 on an uppermost horizontal sacrificial layer of the horizontal sacrificial layers 118, similarly to the first preliminary mold structure MS1p. In the second region R2, a recessed portion or a depression may be formed in the horizontal sacrificial layers 118 and the interlayer insulating layers 120 on the recessed region RC of the first mold structure MS1. A shape of the depression may gradually become gentler toward an upper portion thereof, which may form a notch shape in some layers. For example, the higher the horizontal sacrificial layers 118 and the interlayer insulating layers 120 are positioned, the smaller the degree of the depression becomes. The depression may form key pattern portions KP. The key pattern portions KP may be formed in a region corresponding to a center of the vertical sacrificial layer 119. For example, the key pattern portions KP and the center of the vertical sacrificial layer 119 may overlap when viewed in a plan view.

Referring to FIG. 9H, upper vertical sacrificial layers 119′ penetrating through the second mold structure MS2 may be formed in the first region R1.

The upper vertical sacrificial layers 119′ may be formed in a region corresponding to the second channel structures CH2 of FIG. 2. The upper vertical sacrificial layers 119′ may be formed by forming upper channel holes to penetrate through the second mold structure MS2 to be connected to the vertical sacrificial layers 119, and depositing materials included in the upper vertical sacrificial layers 119′ and performing a planarization process in the upper channel holes. The upper vertical sacrificial layers 119′ may include carbon or a carbon-based material. In this process step, during a photolithography process for forming the upper channel holes, a photomask may be aligned using the key pattern portions KP as an align key.

The upper vertical sacrificial layers 119′ may be formed only in the first region R1 and not in the second region R2. However, in some example embodiments, the upper vertical sacrificial layers 119′ may also be formed on the align key structure KS in the second region R2.

Referring to FIG. 91, channel structures CH may be formed in the first region R1.

The channel structures CH may be formed by removing the vertical sacrificial layers 119 and the upper vertical sacrificial layers 119′ in the first region R1 to form hole-shaped channel holes, and then sequentially depositing at least a portion of a gate dielectric layer 145, a channel layer 140, a channel filling insulating layer 147, and a channel pad 149 in the channel holes (see also FIG. 3B).

The gate dielectric layer 145 may be formed to have a uniform thickness using an ALD or CVD process. In this process step, the gate dielectric layer 145 may be formed in whole or in part, and a portion extending perpendicular to the semiconductor layer 101 along the channel structure CH may be formed. The channel layer 140 may be formed on the gate dielectric layer 145 in the channel hole. The channel filling insulating layer 147 may be formed to fill the channel hole and may be formed of an insulating material. The channel pad 149 may be formed by partially removing the channel filling insulating layer 147 from an upper end of the channel hole and then filling the removed portion with a conductive material, and may be formed of, for example, polycrystalline silicon.

Referring to FIG. 9J, second openings OP2 penetrating through the first preliminary mold structure MS1p and the second mold structure MS2 and exposing the semiconductor layer 101 may be formed in the first region R1, and the first horizontal conductive layer 102 may be formed, and then, the horizontal sacrificial layers 118 may be removed.

First, a second cell region insulating layer 194 may be formed on the upper interlayer insulating layer 125, and the second openings OP2 may be formed in a position corresponding to the separation regions WC (see FIG. 2) in the first region R1. Next, an etch-back process may be performed while forming separate sacrificial spacer layers in the second openings OP2, so that in the first region R1, the horizontal insulating layer 110 may be exposed and the horizontal insulating layer 110 may be removed from the exposed region. The horizontal insulating layer 110 may be removed in, for example, a wet etching process. During the removal process of the horizontal insulating layer 110, a portion of the gate dielectric layer 145 exposed in a region from which the horizontal insulating layer 110 has been removed may also be removed. In the first region R1, after forming the first horizontal conductive layer 102 by depositing a conductive material in the region from which the horizontal insulating layer 110 has been removed, the sacrificial spacer layers may be removed from the second openings OP2. Through this process step, the first horizontal conductive layer 102 may be formed in the first region R1, and a source structure SS including the semiconductor layer 101 and the first and second horizontal conductive layers 102 and 104 may be formed.

Next, the horizontal sacrificial layers 118 may be selectively removed with respect to the interlayer insulating layers 120, the upper interlayer insulating layers 125, and the second horizontal conductive layer 104, using, for example, wet etching, thus forming tunnel portions TL between two adjacent interlayer insulating layers of the interlayer insulating layers 120. In this process step, since the second opening OP2 is not formed in the second region R2, the horizontal insulating layer 110 and the horizontal sacrificial layers 118 may remain.

Referring to FIG. 9K, in the first region R1, gate electrodes 130 may be formed in the tunnel portions TL and separation regions WC may be formed.

In the first region R1, the gate electrodes 130 may be formed by filling the tunnel portions TL from which the horizontal sacrificial layers 118 have been removed, with a conductive material. Accordingly, first and second stack structures GS1 and GS2 including the gate electrodes 130 may be formed in the first region R1. When a portion of the gate dielectric layer 145 extends horizontally along the gate electrodes 130, in this process step, a portion of the gate dielectric layer 145 may be formed before the formation of the gate electrodes 130. The gate electrodes 130 may include a conductive material, for example, a metal, polycrystalline silicon, or a metal silicide material.

After forming the gate electrodes 130, the separation regions WC may be formed by filling the second openings OP2 with an insulating material.

Next, referring to FIG. 2 together, the semiconductor device 100 may be manufactured by forming studs 170 connected to the channel structures CH and cell interconnections 180 in the first region R1.

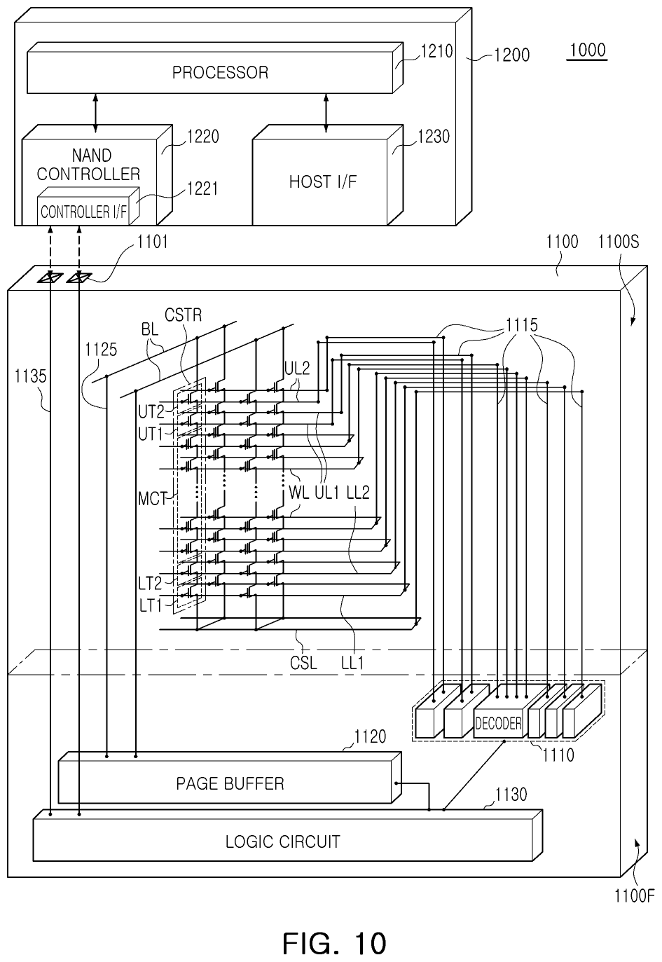

FIG. 10 is a view schematically illustrating a data storage system including a semiconductor device according to example embodiments.

Referring to FIG. 10, the data storage system 1000 may include a semiconductor device 1100 and a controller 1200 electrically connected to the semiconductor device 1100. The data storage system 1000 may be a storage device including one or a plurality of semiconductor devices 1100 or an electronic device including a storage device. For example, the data storage system 1000 may be a solid state drive device (SSD) device, a universal serial bus (USB) device, a computing system, a medical device, or a communication device, including one or a plurality of semiconductor devices 1100.

The semiconductor device 1100 may be a non-volatile memory device, for example, the NAND flash memory device described above with reference to FIGS. 1 to 8. The semiconductor device 1100 may include a first structure 1100F and a second structure 1100S on the first structure 1100F. In example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously modified according to example embodiments.

In example embodiments, the upper transistors UT1 and UT2 may include string select transistors, and the lower transistors LT1 and LT2 may include a ground selection transistor. The gate lower lines LL1 and LL2 may be gate electrodes of the lower transistors LT1 and LT2, respectively. The word lines WL may be gate electrodes of memory cell transistors MCT, and the gate upper lines UL1 and UL2 may be gate electrodes of the upper transistors UT1 and UT2, respectively.

In example embodiments, the lower transistors LT1 and LT2 may include a lower erase control transistor LT1 and a ground selection transistor LT2 connected in series. The upper transistors UT1 and UT2 may include a string select transistor UT1 and an upper erase control transistor UT2 connected in series. At least one of the lower erase control transistor LT1 and the upper erase control transistor UT2 may be used in an erase operation of deleting data stored in memory cell transistors MCT using a GIDL phenomenon.

The common source line CSL, the first and second gate lower lines LL1 and LL2, the word lines WL, and the first and second gate upper lines UL1 and UL2 may be electrically connected to a decoder circuit 1110 through first connection interconnections 1115 extending from the first structure 1100F to the second structure 1100S. The bit lines BL may be electrically connected to a page buffer 1120 through second connection interconnections 1125 extending from the first structure 1100F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by a logic circuit 1130. The semiconductor device 1100 may communicate with a controller 1200 through an input/output pad 1101 electrically connected to the logic circuit 1130. The input/output pad 1101 may be electrically connected to the logic circuit 1130 through an input/output connection interconnection 1135 extending from the first structure 1100F to the second structure 1100S.

The controller 1200 may include a processor 1210, a NAND controller 1220, and a host interface 1230. According to example embodiments, the data storage system 1000 may include a plurality of semiconductor devices 1100, and in this case, the controller 1200 may control a plurality of semiconductor devices 1100.

The processor 1210 may control an overall operation of the data storage system 1000, including the controller 1200. The processor 1210 may operate according to predetermined firmware, and may control the NAND controller 1220 to access the semiconductor device 1100. The NAND controller 1220 may include a controller interface 1221 configured to process communication with the semiconductor device 1100. Through the controller interface 1221, control commands for controlling the semiconductor device 1100, data to be recorded in the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When receiving the control commands from an external host through the host interface 1230, the processor 1210 may control the semiconductor device 1100 in response to the control commands.

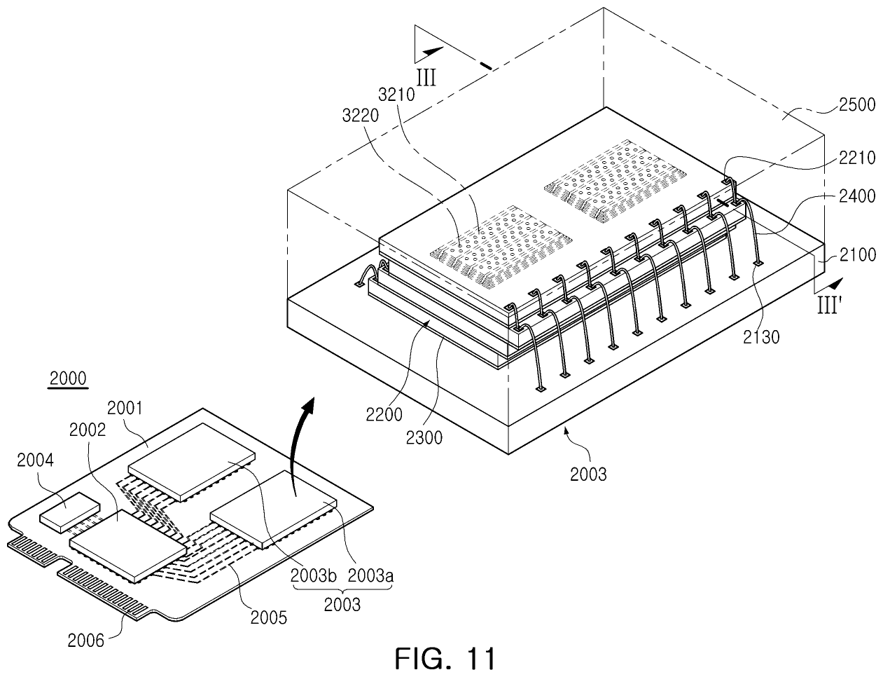

FIG. 11 is a perspective view schematically illustrating a data storage system including a semiconductor device according to an example embodiment.

Referring to FIG. 11, a data storage system 2000 may include a main board 2001, a controller 2002 mounted on the main board 2001, one or more semiconductor packages 2003, and DRAM 2004. The semiconductor package 2003 and the DRAM 2004 may be connected to the controller 2002 through interconnection patterns 2005 formed on the main board 2001.

The main board 2001 may include a connector 2006 including a plurality of pins coupled to an external host. The number and arrangement of the plurality of pins in the connector 2006 may vary, depending on the communication interface between the data storage system 2000 and the external host. In example embodiments, the data storage system 2000 may communicate with an external host according to any one of the interfaces of M-Phy for Universal Serial Bus (USB), Peripheral Component Interconnect Express (PCI-Express), Serial Advanced Technology Attachment (SATA), and Universal Flash Storage (UFS). In example embodiments, the data storage system 2000 may operate with power supplied from the external host through the connector 2006. The data storage system 2000 may further include a Power Management Integrated Circuit (PMIC) that distributes power supplied from the external host to the controller 2002 and the semiconductor package 2003.

The controller 2002 may record data to the semiconductor package 2003 or read data from the semiconductor package 2003, and may improve the operating speed of the data storage system 2000.

The DRAM 2004 may be a buffer memory to alleviate a speed difference between the semiconductor package 2003 as a data storage space and an external host. The DRAM 2004 included in the data storage system 2000 may also operate as a type of cache memory, and may provide a space for temporarily storing data in control operations for the semiconductor package 2003. When the data storage system 2000 includes the DRAM 2004, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may include a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including the upper pads 2130. Each semiconductor chip 2200 may include an input/output pad 2210. The input/output pad 2210 may correspond to the input/output pad 1101 of FIG. 10. Each of the semiconductor chips 2200 may include gate stack structures 3210 and channel structures 3220. Each of the semiconductor chips 2200 may include the semiconductor device described above with reference to FIGS. 1 to 8.

In example embodiments, the connection structure 2400 may be a bonding wire that electrically connects the input/output pad 2210 and the upper pads 2130. Accordingly, in each of the first and second semiconductor packages 2003a and 2003b, the semiconductor chips 2200 may be electrically connected to each other using a bonding wire method, and may be electrically connected to the upper pads 2130 of the package substrate 2100. According to example embodiments, in each of the first and second semiconductor packages 2003a and 2003b, the semiconductor chips 2200 may be electrically connected to each other by a connection structure including a through silicon Via (TSV), instead of the connection structure 2400 of the bonding wire method.

In example embodiments, the controller 2002 and the semiconductor chips 2200 may be included in one package. In an exemplary embodiment, the controller 2002 and the semiconductor chips 2200 may be mounted on a separate interposer substrate different from the main board 2001, and the controller 2002 and the semiconductor chips 2200 may be connected to each other through interconnections formed on the interposer substrate.

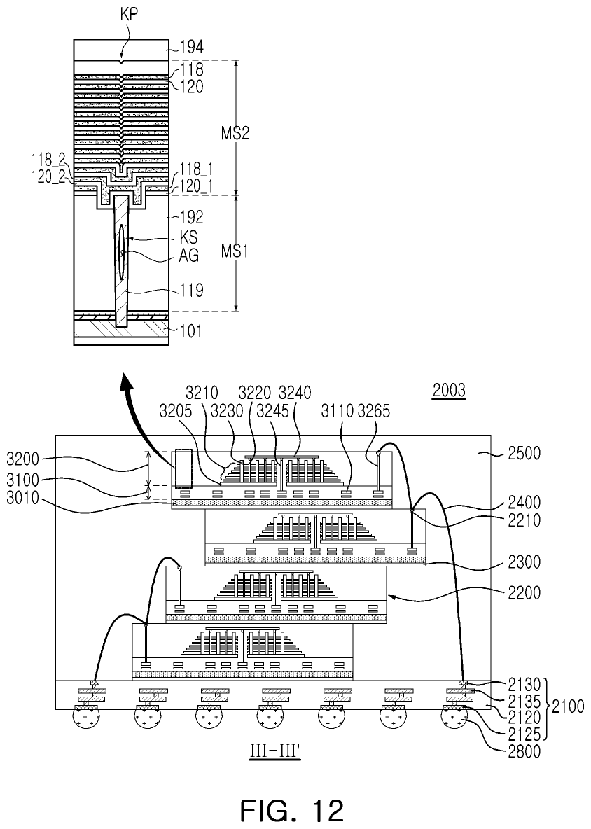

FIG. 12 is a cross-sectional view schematically illustrating a semiconductor package according to an example embodiment. FIG. 12 illustrates an example embodiment of the semiconductor package 2003 of FIG. 11, and conceptually represents a region in which the semiconductor package 2003 of FIG. 11 is cut along line III-III′.

Referring to FIG. 12, in the semiconductor package 2003, the package substrate 2100 may be a printed circuit board. The package substrate 2100 may include a package substrate body 2120, upper pads 2130 disposed at an upper surface of the package substrate body 2120, lower pads 2125 disposed at or exposed through a lower surface of the package substrate body 2120, and internal interconnections 2135 electrically connecting the upper pads 2130 to the lower pads 2125 inside the package substrate body 2120. The upper pads 2130 may be electrically connected to the connection structures 2400. The lower pads 2125 may be connected to the interconnection patterns 2005 of the main board 2001 of the data storage system 2000 as illustrated in FIG. 11 through conductive connectors 2800.

Each of the semiconductor chips 2200 may include a semiconductor substrate 3010 and a first structure 3100 and a second structure 3200 sequentially stacked on the semiconductor substrate 3010. The first structure 3100 may include a peripheral circuit region including peripheral interconnections 3110. The second structure 3200 may include a common source line 3205, a gate stack structure 3210 on the common source line 3205, channel structures 3220 and separation regions 3230 penetrating through the gate stack structure 3210, and bit lines 3240 electrically connected to the channel structures 3220. As described above with reference to FIGS. 1 to 8, a key pattern portion KP and an align key structure KS for alignment during the manufacturing process may be disposed in one region of each of the semiconductor chips 2200.

Each of the semiconductor chips 2200 may include a through-interconnection 3245 electrically connected to the peripheral interconnections 3110 of the first structure 3100 and extending into the second structure 3200. The through-interconnection 3245 may be disposed outside the gate stack structure 3210, and may be further disposed to penetrate through the gate stack structure 3210. Each of the semiconductor chips 2200 may further include an input/output connection interconnection 3265 electrically connected to the peripheral interconnections 3110 of the first structure 3100 and extending into the second structure 3200, and an input/output pad 2210 electrically connected to the input/output connection interconnection 3265.

The present disclosure is not limited to the above-described embodiments and the accompanying drawings but is defined by the appended claims. Therefore, those of ordinary skill in the art may make various replacements, modifications, changes, or combinations of embodiments without departing from the scope of the present disclosure defined by the appended claims, and these replacements, modifications, changes, or combinations of embodiments should be construed as being included in the scope of the present disclosure.

What is claimed is:

1. A semiconductor device comprising:
a semiconductor layer;
a plurality of first gate electrodes disposed in a first region of the semiconductor device, wherein the plurality of first gate electrodes are spaced apart from each other and stacked in a first direction perpendicular to an upper surface of the semiconductor layer to form a first stack structure;
a plurality of second gate electrodes stacked in the first direction to form a second stack structure, wherein the second stack structure is disposed on the first stack structure;
a channel structure including a first channel structure and a second channel structure penetrating through the first stack structure and the second stack structure, respectively, wherein the first channel structure includes an upper end contacting a lower end of the second channel structure and a lower end contacting the semiconductor layer;
a first mold structure in a second region, wherein the second region is spaced apart from the first region in a first horizontal direction parallel to the upper surface of the semiconductor layer;
an align key structure penetrating through the first mold structure and contacting the semiconductor layer; and
a second mold structure disposed on the first mold structure and the align key structure and including a plurality of interlayer insulating layers and a plurality of horizontal sacrificial layers alternately stacked in the first direction, wherein the second mold structure includes a first interlayer insulating layer of the plurality of interlayer insulating layers, a first horizontal sacrificial layer of the plurality of horizontal sacrificial layers, a second interlayer insulating layer of the plurality of interlayer insulating layers, and a second horizontal sacrificial layer of the plurality of horizontal sacrificial layers sequentially stacked on an upper surface of the first mold structure in the first direction,
wherein the first interlayer insulating layer and the first horizontal sacrificial layer are spaced apart from the align key structure in a horizontal direction when viewed in a plan view, and
wherein the second interlayer insulating layer covers an upper surface and a portion of a side surface of the align key structure.

2. The semiconductor device of claim 1,
wherein the second interlayer insulating layer includes a vertical portion extending in the first direction and covering a side surface of the first interlayer insulating layer and a side surface of the first horizontal sacrificial layer, and
wherein the vertical portion of the second interlayer insulating layer is around the portion of the side surface of the align key structure.

3. The semiconductor device of claim 1,
wherein the second interlayer insulating layer includes a first horizontal portion on the upper surface of the align key structure, a second horizontal portion on a recessed upper surface of the first mold structure around the align key structure, and a third horizontal portion on an upper surface of the first horizontal sacrificial layer, and wherein the first horizontal portion is higher than the second horizontal portion and lower than the third horizontal portion.

4. The semiconductor device of claim 1,
wherein the upper end of the first channel structure in the first stack structure has a width greater than a width of the lower end of the second channel structure in the second stack structure, and
wherein in the second stack structure, a lowermost second gate electrode among the plurality of second gate electrodes is disposed at a same level as the first horizontal sacrificial layer.

5. The semiconductor device of claim 1,
wherein the first mold structure includes an insulating layer in contact with the first interlayer insulating layer, and
wherein the insulating layer has a recessed region exposing the upper surface and the portion of the side surface of the align key structure.

6. The semiconductor device of claim 5,
wherein the second interlayer insulating layer and the second horizontal sacrificial layer fills the recessed region.

7. The semiconductor device of claim 1,
wherein the align key structure includes carbon (C), and
wherein the first interlayer insulating layer includes oxide.

8. The semiconductor device of claim 1,
wherein the first region is a memory cell region in which the first stack structure and the second stack structure form memory cells, and
wherein the second region is a scribe lane region.

9. The semiconductor device of claim 1,
wherein the plurality of horizontal sacrificial layers have a plurality of key pattern portions overlapping the align key structure, and
wherein the plurality of key pattern portions correspond to recessed portions of the plurality of horizontal sacrificial layers.

10. The semiconductor device of claim 1,
wherein the upper surface of the align key structure is disposed at a same level as an uppermost surface of the first mold structure.

11. The semiconductor device of claim 1,
wherein the first mold structure is formed of a single insulating material.

12. The semiconductor device of claim 1,
wherein an upper surface of the first channel structure is disposed at a same level as the upper surface of the align key structure.

13. The semiconductor device of claim 1,
wherein the align key structure overlaps the plurality of horizontal sacrificial layers in the first direction.

14. A semiconductor device comprising:
a semiconductor layer;
a plurality of gate electrodes disposed in a first region of the semiconductor device to form a first stack structure and a second stack structure, wherein the second stack structure is disposed on the first stack structure in a first direction perpendicular to an upper surface of the semiconductor layer, wherein the plurality of gate electrodes are spaced apart from each other and stacked in the first direction, and wherein the plurality of gate electrodes include a plurality of first gate electrodes in the first stack structure and a plurality of second gate electrodes in the second stack structure;
a channel structure penetrating through the first stack structure and the second stack structure and contacting the semiconductor layer;
a first mold structure in a second region spaced apart from the first region in a first horizontal direction parallel to the upper surface of the semiconductor layer;
an align key structure penetrating through the first mold structure; and
a second mold structure disposed on the first mold structure and the align key structure and including a first interlayer insulating layer, a first horizontal sacrificial layer, a second interlayer insulating layer and a second horizontal sacrificial layer sequentially stacked on an upper surface of the first mold structure,
wherein the first mold structure has a recessed region exposing an upper surface and a portion of a side surface of the align key structure,
wherein the first interlayer insulating layer and the first horizontal sacrificial layer are outside the recessed region when viewed in a plan view, and
wherein a lower surface of a lowermost second gate electrode of the plurality of second gate electrodes in the second stack structure is disposed at a same level as a lower surface of the first horizontal sacrificial layer.

15. The semiconductor device of claim 14,
wherein the first interlayer insulating layer and the first horizontal sacrificial layer are outside of the recessed region when viewed in the plan view, and
wherein the second interlayer insulating layer is disposed in the recessed region.

16. The semiconductor device of claim 14,
wherein a thickness of the first horizontal sacrificial layer is equal to or greater than a thickness of the first interlayer insulating layer.

17. The semiconductor device of claim 14,
wherein a thickness of the first horizontal sacrificial layer is equal to a thickness of the lowermost second gate electrode.

18. The semiconductor device of claim 14,
wherein one of the plurality of second gate electrodes adjacent to the lowermost second gate electrode is disposed at a same level as the second horizontal sacrificial layer.

19. A data storage system comprising:
a semiconductor storage device including a semiconductor layer, circuit elements on one side of the semiconductor layer, and an input/output pad electrically connected to the circuit elements, and having a first region and a second region; and
a controller electrically connected to the semiconductor storage device through the input/output pad and configured to control the semiconductor storage device,
wherein the semiconductor storage device includes:
a plurality of gate electrodes disposed in the first region to form a first stack structure and a second stack structure,
wherein the second stack structure is disposed on the first stack structure in a first direction perpendicular to an upper surface of the semiconductor layer,
wherein the plurality of gate electrodes are spaced apart from each other and stacked in the first direction, and
wherein the plurality of gate electrodes include a plurality of first gate electrodes in the first stack structure and a plurality of second gate electrodes in the second stack structure;
a channel structure penetrating through the first stack structure and the second stack structure and contacting the semiconductor layer;
a first mold structure in the second region;
an align key structure penetrating through the first mold structure; and
a second mold structure disposed on the first mold structure and the align key structure and including a first interlayer insulating layer, a first horizontal sacrificial layer, and a second interlayer insulating layer sequentially stacked on an upper surface of the first mold structure,
wherein the first interlayer insulating layer and the first horizontal sacrificial layer are spaced apart from the align key structure in a horizontal direction parallel to the upper surface of the semiconductor layer, and
wherein a lowermost second gate electrode of the plurality of second gate electrodes in the second stack structure is disposed at a same level as the first horizontal sacrificial layer.

20. The data storage system of claim 19,
wherein the second interlayer insulating layer covers an upper surface and a portion of a side surface of the align key structure.
